(19) United States
(12) Patent Application Publication
(10) Pub. No.: US 2014/0232959 A1
(43) Pub. Date: Aug. 21, 2014

(54) CONDUCTIVE FILM AND TOUCH PANEL

(71) Applicant: FUJIFILM CORPORATION, Tokyo (JP)

(72) Inventor: Tadashi KURIKI, Ashigarakami-gun (JP)

(73) Assignee: FUJIFILM CORPORATION, Tokyo (JP)

(21) Appl. No.: 14/262,132

(22) Filed: Apr. 25, 2014

Related U.S. Application Data
(63) Continuation of application No. PCT/JP2012/077589, filed on Oct. 25, 2012.

(30) Foreign Application Priority Data
Oct. 27, 2011 (JP) 2011-235997

(51) Int. Cl. G06F 1/16; H05K 1/02

(52) U.S. Cl. CPC G06F 1/1692; H05K 1/02
USPC 349/12; 174/250

(57) ABSTRACT

A first conductive unit of a first conductive film has two or more first conductive patterns made from fine metal wires and including multiple first pads connected through a first connection part. The first pad units are provided with a first spiral unit which extends from one of the first connection units, a second spiral unit which extends from the other first connection unit, and a first connection unit which connects the first spiral unit and the second spiral unit. The first spiral unit and the second spiral unit are configured such that the grids thereof combine, and the first connection unit is configured from multiple conducting wires.

### CROSS-REFERENCE TO RELATED APPLICATIONS AND PRIORITY CLAIM

This application is a Continuation of International Application No. PCT/JP2012/077589 filed on Oct. 25, 2012, which was published under PCT Article 21(2) in Japanese, which is based upon and claims the benefit of priority from Japanese Patent Application No. 2011-235997 filed on Oct. 27, 2011, the contents all of which are incorporated herein by reference.

### TECHNICAL FIELD

The present invention relates to a conductive film and a touch panel having a conductive film.

### BACKGROUND ART

Touch panels have been used mainly in small devices such as PDAs (personal digital assistants) and mobile phones, and are expected to be used in large devices such as personal computer displays.

A conventional electrode for a touch panel is composed of ITO (indium tin oxide) and therefore has a high resistance. Thus, according to the above future trend, on the condition that the conventional electrode is used in a large device, the large-sized touch panel has a low current transfer rate between the electrodes, and thereby exhibits a low response speed (a long time between finger contact and touch position detection).

A large number of lattices made up of thin wires of metal (thin metal wires) can be arranged in order to form an electrode with lowered surface resistance. Touch panels, which use an electrode made up of such thin metal wires, are known from U.S. Pat. No. 5,113,041, International Publication No. 95/027334, U.S. Patent Application Publication No. 2004/0239650, and U.S. Pat. No. 7,202,859, etc.

### SUMMARY OF INVENTION

The conductive film according to U.S. Patent Application Publication No. 2004/0239650 or U.S. Pat. No. 7,202,859 includes a first conductive pattern formed by arranging thin metal wires each having a plurality of S-shaped deformed portions in the vertical direction, and a second conductive pattern formed by arranging thin metal wires each having a plurality of S-shaped deformed portions in the horizontal direction. The first and second conductive patterns are arranged such that the deformed portions overlap with each other. In this case, the overlapping portions of the thin metal wires in the first and second conductive patterns and in the vicinity thereof function as charge storage cells.

However, a line width, which is suitable for practical use, is not known from the above documents. Further, on the condition that one of the thin metal wires is broken, a disadvantage occurs in that the address associated with the broken wire cannot be recognized. In the examples of FIGS. 15 and 16, which are shown in U.S. Patent Application Publication No. 2004/0239650, the negative impact of such breakage can be reduced by thickening the ladder pattern or the hex pattern, by increasing the brickwork number, or by reducing the distance between the bricks, etc. However, in this case, the light transmittance of the conductive film is deteriorated, the touch panel that uses the conductive film exhibits low display brightness, and the content displayed on the touch panel becomes less visible. In addition, in the example of FIG. 15, which is shown in US Patent Application Publication No. 2004/0239650, boundaries between the ladder patterns in the first and second conductive patterns are highly visible, and the conductive film is disadvantageous in terms of visibility (i.e., in that the conductive patterns can be visually observed by the naked eye).

In view of the above problems, an object of the present invention is to provide a conductive film and a touch panel, which are capable of exhibiting excellent light transmittance, excellent visibility, an improved output dynamic range to input, improved touch position detection sensitivity, and improved detection accuracy.

[1] A conductive film according to a first aspect of the present invention comprises a substrate and a conductive part formed on one main surface of the substrate, wherein the conductive part contains two or more conductive patterns composed of a thin metal wire, the conductive patterns each contain a plurality of pad portions connected by connections, the pad portions each contain a first spiral extending from one of the connections, a second spiral extending from an opposite connection, and a linkage for linking the first and second spirals, the first and second spirals each contain a combination of a plurality of lattices, and the linkage contains a plurality of conductive wires.

[2] In the first aspect of the present invention, edges of the first and second spirals each have a concavo-convex shape having peaks and troughs at vertices of the lattices.

[3] In the first aspect of the present invention, each of a plurality of the conductive wires in the linkage have a straight line shape.

[4] In the first aspect of the present invention, the conductive part contains a dummy pattern between the conductive patterns, the dummy pattern being composed of a thin metal wire that is not connected to the conductive patterns.

[5] In the first aspect of the present invention, the dummy pattern is positioned between the connection in one of the conductive patterns and the connection in an opposite conductive pattern.

[6] In the first aspect of the present invention, edges of the first and second spirals each have two or more long sides and a protrusion, the long sides each contain sides of the lattices arranged adjacently along a straight line, and the protrusion is composed of a thin metal wire, which extends perpendicularly from at least one of the long sides.

[7] A conductive film according to a second aspect of the present invention comprises a substrate, a first conductive part formed on one main surface of the substrate, and a second conductive part formed on another main surface of the substrate, wherein the first conductive part contains two or more first conductive patterns composed of a thin metal wire, the first conductive patterns each contain a plurality of first pad portions connected by first connections, the second conductive part contains two or more second conductive patterns composed of a thin metal wire, the second conductive patterns each contain a plurality of second pad portions connected by second connections, the first pad portions each contain a first spiral extending from one of the first connections, a second spiral extending from an opposite first connection, and a first linkage for linking the first spiral and the second spiral, the second pad portions each contain a third spiral extending from one of the second connections, a fourth spiral extending from an opposite second connection, and a second linkage for linking the third and fourth spirals, the first to fourth spirals each contain a combination of a plurality of lattices, the first linkage and the second linkage each contain a plurality of conductive wires, and the first conductive patterns and the second conductive patterns are arranged such that the first linkage and the second linkage intersect in a substantially perpendicular manner.

[8] In the second aspect of the present invention, edges of the first to fourth spirals each have a concavo-convex shape having peaks and troughs at vertices of the lattices.

[9] In the second aspect of the present invention, the first conductive patterns and the second conductive patterns are arranged such that the second connection is positioned between adjacent first conductive patterns, and the first connection is positioned between adjacent second conductive patterns.

[10] In the second aspect of the present invention, the first conductive patterns and the second conductive patterns are arranged such that the third spiral or the fourth spiral in the second conductive pattern is positioned between the first spiral and the second spiral in the first conductive pattern, and the first spiral or the second spiral in the first conductive pattern is positioned between the third spiral and the fourth spiral in the second conductive pattern.

[11] In the second aspect of the present invention, the first conductive part contains a first dummy pattern between the first conductive patterns, the first dummy pattern being composed of a thin metal wire that is not connected to the first conductive patterns, and the second conductive part contains a second dummy pattern between the second conductive patterns, the second dummy pattern being composed of a thin metal wire that is not connected to the second conductive patterns.

[12] In the second aspect of the present invention, the first dummy pattern is positioned between the first connection in one of the first conductive patterns and the first connection in an opposite first conductive pattern, and the second dummy pattern is positioned between the second connection in one of the second conductive patterns and the second connection in an opposite second conductive pattern.

[13] In the second aspect of the present invention, the first conductive patterns and the second conductive patterns are arranged such that the second connection is positioned between the first dummy patterns, and the first connection is positioned between the second dummy patterns.

[14] In the second aspect of the present invention, the number of lattices in the first spiral and the second spiral in the first conductive pattern is smaller than the number of lattices in the third spiral and the fourth spiral in the second conductive pattern.

[15] In the second aspect of the present invention, edges of the first spiral and the second spiral each have two or more first long sides and a first protrusion, the first long sides each contain sides of the lattices arranged adjacently along a straight line, the first protrusion is composed of a thin metal wire, which extends perpendicularly from at least one of the first long sides, edges of the third spiral and the fourth spiral each have two or more second long sides and a second protrusion, the second long sides each contain sides of the lattices arranged adjacently along a straight line, and the second protrusion is composed of a thin metal wire, which extends perpendicularly from at least one of the second long sides.

[16] In the second aspect of the present invention, the first long side that has the first protrusion and the second long side that does not have the second protrusion are arranged in facing relation to each other.

[17] In the second aspect of the present invention, the first long side that does not have the first protrusion and the second long side that has the second protrusion are arranged in facing relation to each other.

[18] In the first and second aspects of the present invention, the lattices have a side length of 100 to 400 μm.

[19] In the first and second aspects of the present invention, the lattices have a line width of 1 to 15 μm.

[20] A touch panel according to a third aspect of the present invention comprises a conductive film, which is used in a display panel of a display device, wherein the conductive film contains a substrate and a conductive part formed on one main surface of the substrate, the conductive part contains two or more conductive patterns composed of a thin metal wire, the conductive patterns each contain a plurality of pad portions connected by connections, the pad portions each contain a first spiral extending from one of the connections, a second spiral extending from an opposite connection, and a linkage for linking the first and second spirals, the first and second spirals each contain a combination of a plurality of lattices, and the linkage contains a plurality of conductive wires.

[21] A touch panel according to a fourth aspect of the present invention comprises a conductive film, which is used in a display panel of a display device, wherein the conductive film contains a substrate, a first conductive part formed on one main surface of the substrate, and a second conductive part formed on another main surface of the substrate, the first conductive part contains two or more first conductive patterns composed of a thin metal wire, the first conductive patterns each contain a plurality of first pad portions connected by first connections, the second conductive part contains two or more second conductive patterns composed of a thin metal wire, the second conductive patterns each contain a plurality of second pad portions connected by second connections, the first pad portions each contain a first spiral extending from one of the first connections, a second spiral extending from an opposite first connection, and a first linkage for linking the first spiral and the second spiral, the second pad portions each contain a third spiral extending from one of the second connections, a fourth spiral extending from an opposite second connection, and a second linkage for linking the third spiral and the fourth spiral, the first to the fourth spirals each contain a combination of a plurality of lattices, the first linkage and the second linkage each contain a plurality of conductive wires, and the first conductive patterns and the second conductive patterns are arranged such that the first linkage and the second linkage intersect in a substantially perpendicular manner.

As described above, the conductive film and the touch panel of the present invention are excellent in terms of light transmittance and visibility, and can exhibit an improved output dynamic range from to input, improved touch position detection sensitivity, and improved detection accuracy.

The above objects, features, and advantages of the present invention will become more apparent from the following description when taken in conjunction with the accompanying drawings.

### BRIEF DESCRIPTION OF DRAWINGS

FIG. 1 is a partial plan view of a pattern of a first conductive part on a conductive film (first conductive film) according to a first embodiment of the present invention;

FIG. 2 is a partial cross-sectional view of the first conductive film;

FIG. 3 is an enlarged plan view of a first pad portion, a first connection, and a first dummy pattern on the first conductive film;

FIG. 4 is an exploded perspective view of a touch panel having a conductive film stack;

FIG. 5 is a partial exploded perspective view of the conductive film stack;

FIG. 6A is a partial cross-sectional view of an example of the conductive film stack, and FIG. 6B is a partial cross-sectional view of another example of the conductive film stack;

FIG. 7 is a partial plan view of a pattern of a second conductive part on a conductive film (second conductive film) according to a second embodiment of the present invention;

FIG. 8 is an enlarged plan view of a second pad portion, a second connection, and a second dummy pattern on the second conductive film;

FIG. 9 is a partial plan view of the conductive film stack formed by combining the first and second conductive films;

FIG. 10 is a flow chart of a method for producing a conductive film stack according to the present invention;

FIG. 11A is a partial cross-sectional view of a produced photosensitive material, and FIG. 11B is an explanatory view for illustrating simultaneous two-side exposure of the photosensitive material; and

FIG. 12 is an explanatory view for illustrating first and second exposure treatments performed such that light incident on a first photosensitive layer does not reach a second photosensitive layer, and light incident on the second photosensitive layer does not reach the first photosensitive layer.

### DESCRIPTION OF EMBODIMENTS

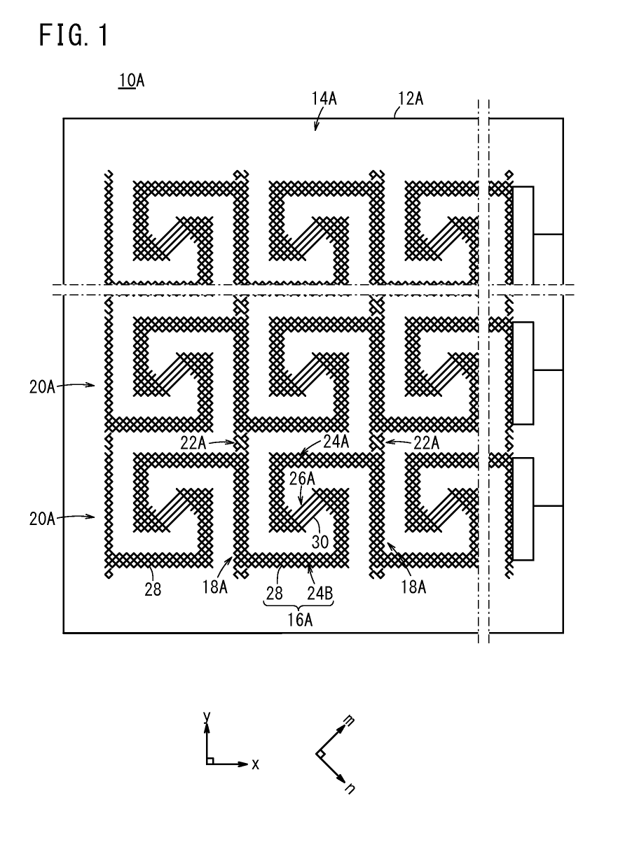

Several embodiments of the conductive film and the display device containing the conductive film according to the present invention will be described below with reference to FIGS. 1 to 12. It should be noted that, in the present description, in the event that a numerical range of “A to B” is stated, the numerical range includes both the numerical values A and B as lower limit and upper limit values thereof.

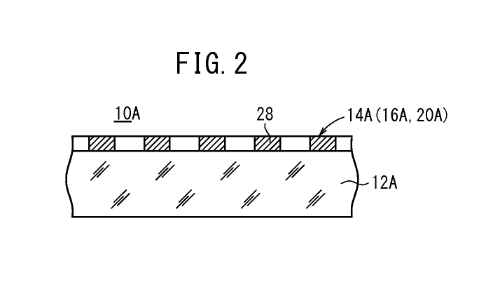

As shown in FIG. 1, a conductive film according to a first embodiment (hereinafter referred to as a first conductive film 10A) has a first conductive part 14A formed on one main surface of a first transparent substrate 12A (see FIG. 2). The first conductive part 14A contains two or more first conductive patterns 20A with first dummy patterns 22A disposed therebetween. Each of the first conductive patterns 20A is composed of thin metal wires and contains a plurality of first pad portions 16A, which are connected with each other by a first connection 18A. Each of the first dummy patterns 22A is composed of thin metal wires, which are not connected to the first conductive patterns 20A. The thin metal wires are constituted, for example, from gold (Au), silver (Ag), or copper (Cu).

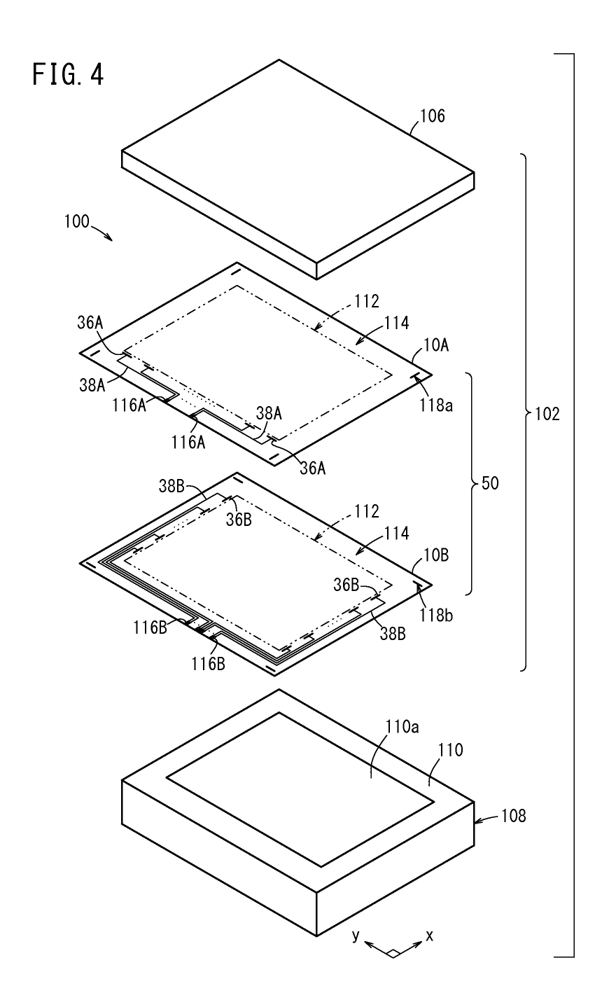

Two or more first pad portions 16A are arranged in an x direction (a first direction) with the first connection 18A disposed therebetween so as to form the first conductive pattern 20A. Two or more first conductive patterns 20A are arranged in a y direction (a second direction) perpendicular to the x direction. For example, the x direction corresponds to a horizontal (or a vertical direction) of a projected capacitive touch panel 100 or a display panel 110 equipped with such a touch panel 100, which will be described hereinafter (see FIG. 4).

The first pad portion 16A has a first spiral 24A extending from one first connection 18A, a second spiral 24B extending from an opposite first connection 18A, and a first linkage 26A that links the first spiral 24A and the second spiral 24B. The first spiral 24A, the second spiral 24B, and the first connection 18A each contain a combination made up of a plurality of lattices 28. The first linkage 26A contains a plurality of conductive wires 30. In the present embodiment, the lattices 28 have a smallest square or rhombus shape.

The side length of the first pad portion 16A preferably is 3 to 10 mm, and more preferably, is 4 to 6 mm. On the condition that the side length is less than the lower limit, the first pad portion 16A exhibits a lowered electrostatic capacitance during a detection process of a touch panel or the like in which the first conductive film 10A is used, and thus, the touch panel is likely to experience detection troubles. On the other hand, on the condition that the side length is greater than the upper limit, the accuracy in position detection may become deteriorated. For the same reasons, the side length of the lattice 28 in the first pad portion 16A preferably is 100 to 400 μm, more preferably, is 150 to 300 μm, and most preferably, is 210 to 250 μm. On the condition that the side length of the lattice 28 lies within such a range, the first conductive film 10A exhibits high transparency (light transmissibility) and thus can be used suitably on the front of a display device while providing excellent visibility. The line width of the lattice 28, i.e., the thin metal wire, is 1 to 15 μm. On the condition that the line width and the side length of the lattice 28 lie within the aforementioned ranges, conductivity and transparency (light transmissibility) are further improved.

Edges of the first spiral 24A and the second spiral 24B each have a concavo-convex shape having peaks and troughs at the vertices of the lattices 28. The lattices 28 are arranged in the following manner, for example, in order to form the concavo-convex shape. A third direction (an m direction) bisects an angle between the first and second directions, and a fourth direction (an n direction) is perpendicular to the third direction. In the first spiral 24A, three lattices 28 are arranged in the fourth direction (the n direction) so as to form an array (i.e., the sides of the lattices 28 are arranged adjacent to each other). A plurality of such arrays are arranged from one of the first connections 18A toward another of the first connections 18A, and further are arranged in the second direction from a corner of the first spiral 24A. In particular, on a side adjacent to the first linkage 26A (at the end of the first spiral 24A), eight lattices 28 are arranged in the fourth direction. On the eight lattices 28, six lattices, four lattices, and two lattices are arranged sequentially in the second direction. Thus, the number of lattices 28 is reduced by 2 in the second direction.

The second spiral 24B has a similar structure. In the second spiral 24B, three lattices 28 are arranged in the fourth direction (the n direction) so as to form an array. A plurality of such arrays are arranged from the other of the first connections 18A toward the one of the first connections 18A, and further are arranged in the second direction from a corner of the second spiral 24B. On a side adjacent to the first linkage 26A (at the end of the second spiral 24B), eight lattices 28 are arranged in the fourth direction. On the eight lattices 28, six lattices, four lattices, and two lattices are arranged sequentially in the second direction. Thus, the number of lattices 28 is reduced by 2 in the second direction.

It should be understood that, although in the above description, the arrangement of the lattices 28 is described primarily in relation to the fourth direction, the arrangement can be described in relation to the third direction, or in relation to a combination of the third and fourth directions.

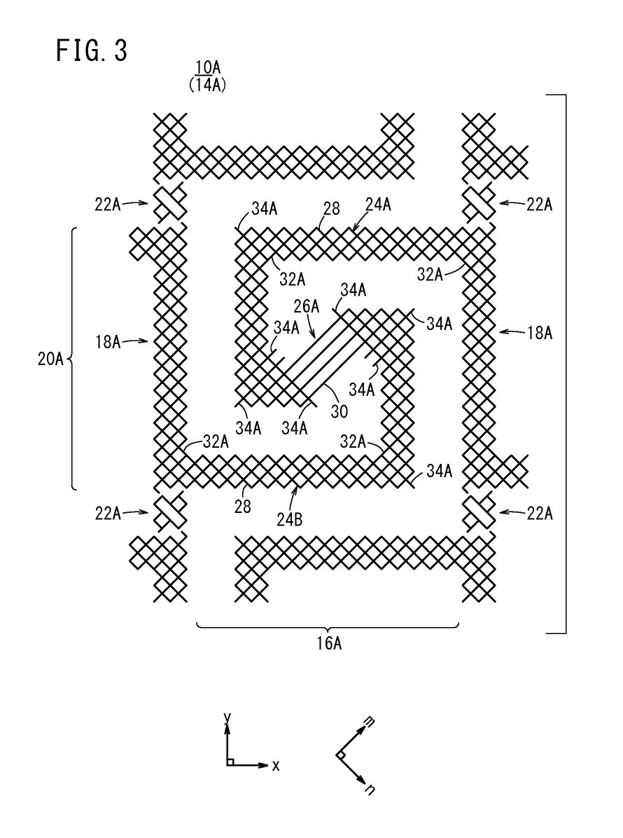

As shown in FIG. 3, two or more first long sides 32A and first protrusions 34A are formed on the edges of the first spiral 24A and the second spiral 24B. The first long side 32A is formed by arranging the sides of the lattices 28 adjacently along a straight line. The first protrusion 34A is composed of a thin metal wire that extends perpendicularly from at least one of the first long sides 32A. More specifically, on the edges of the first spiral 24A and the second spiral 24B, the first long sides 32A are formed on the inside of the corners thereof, and the first protrusions 34A of the thin metal wires are formed on the outside of the corners and the ends thereof.

For example, the first linkage 26A contains four straight conductive wires 30 that extend in the third direction. In the example of FIGS. 1 and 3, the length of the conductive wire 30 is 8 times greater than the side length of the lattice 28. The length of the conductive wire 30 depends on the distance between the first spiral 24A and the second spiral 24B, and may be an integral multiple of the side length of the lattice 28. The direction in which the conductive wires 30 extend is not limited to the third direction, and may be selected from the first direction, the second direction, the fourth direction, or the like, depending on the positions of the ends of the first spiral 24A and the second spiral 24B.

The first dummy patterns 22A are formed between two adjacent first conductive patterns 20A. More specifically, each of the first dummy patterns 22A is disposed between the first connection 18A of one of the first conductive patterns 20A and the first connection 18A of another of the first conductive patterns 20A. In the example of FIGS. 1 and 3, the first dummy pattern 22A is disposed such that the first connections 18A are connected by the lattices 28 (for example, by arranging three lattices 28 in the third or fourth direction so as to form an array, and by arranging the arrays in the second direction), and in the connection, certain ones of the thin metal wires are removed from the lattices 28. For example, the thin metal wires at the center and the thin metal wires in the vicinity of an end of each of the first connections 18A are removed in order to form the first dummy pattern 22A.

In the first conductive film 10A, which has the above structure, one end of each of the first conductive patterns 20A is an open end. At the other end of the first conductive pattern 20A, for example, an end of the first pad portion 16A is connected electrically by a first wire connection 36A to a first terminal wiring pattern 38A, which is composed of a thin metal wire (see FIG. 4).

As described above, in the first conductive film 10A, two or more first pad portions 16A are arranged in the x direction, with the first connections 18A being disposed therebetween in the first conductive pattern 20A. The first pad portion 16A has the first spiral 24A, which extends from the one first connection 18A, the second spiral 24B, which extends from the opposite first connection 18A, and the first linkage 26A, which links the first spiral 24A and the second spiral 24B. Each of the first spiral 24A and the second spiral 24B contains a combination of lattices 28, and the first linkage 26A contains a plurality of the conductive wires 30. Therefore, the first conductive film 10A can exhibit a significantly lowered electrical resistance, as compared with conventional structures that use a single ITO film for one electrode. Thus, in the case that the first conductive film 10A is used in a projected capacitive touch panel or the like, both the size and the response speed of the touch panel can easily be increased. Furthermore, a large number of lattices 28 are arranged in each of the first spiral 24A, the second spiral 24B, and the first connection 18A. Therefore, even in the event that the thin metal wire becomes broken locally, the unbroken thin metal wires are capable of maintaining the electrical connection and thereby avoid any negative impact of such breakage. In addition, the first pad portion 16A is capable of storing a large amount of signal charge due to the lattices 28, whereby the output dynamic range to input is increased. Thus, in the case that the first conductive film 10A is used in a touch panel, the sensitivity for detecting a touch position of a finger (detection sensitivity) can be increased, and the ratio of the signal component to the noise component can be increased, whereby the S/N ratio of the detection signal can be improved. This leads to improvements in touch position detection accuracy.

A touch panel 100 that includes the first conductive film 10A therein will be described below with reference to FIGS. 4 to 9.

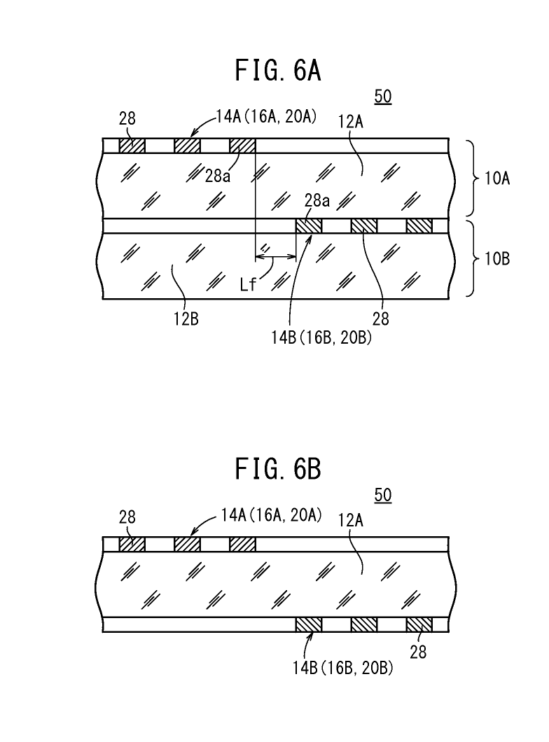

The touch panel 100 has a sensor body 102 and a control circuit such as an input circuit (not shown). As shown in FIGS. 4, 5, and 6A, the sensor body 102 contains a conductive film stack 50 according to the present embodiment, and a protective layer 106 (not shown in FIG. 6A) is disposed on the conductive film stack 50. The conductive film stack 50 is prepared by stacking the first conductive film 10A and a second conductive film 10B, as will be described hereinafter. The conductive film stack 50 and the protective layer 106 can be disposed on a display panel 110 of a display device 108 such as a liquid crystal display. As viewed from above, the sensor body 102 includes a sensing region 112, which corresponds to a display screen 110a of the display panel 110, and a terminal wiring region 114 (a so-called frame), which corresponds to the periphery of the display panel 110.

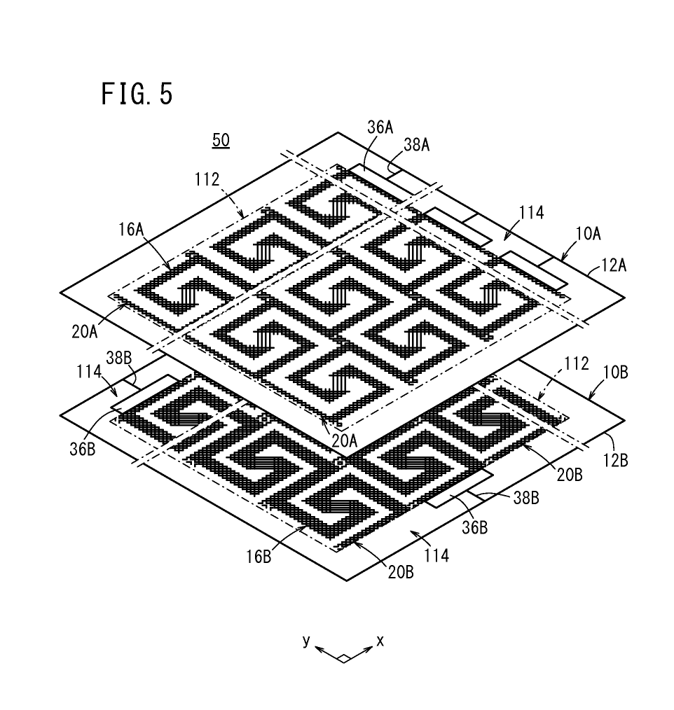

As shown in FIG. 5, in the first conductive film 10A that is used in the touch panel 100, a large number of the above-described first conductive patterns 20A are arranged in the sensing region 112, and plural first terminal wiring patterns 38A, which are composed of thin metal wires, extend from the first wire connections 36A in the terminal wiring region 114.

In the example of FIG. 4, the first conductive film 10A and the sensing region 112 each have a rectangular shape as viewed from above. In the terminal wiring region 114, a plurality of first terminals 116A are arranged in the longitudinal center in the lengthwise direction of the periphery on one long side of the first conductive film 10A. A plurality of the first wire connections 36A are arranged in a straight line in the y direction along one long side of the sensing region 112 (a long side closest to the one long side of the first conductive film 10A). A first terminal wiring pattern 38A extends from each first wire connection 36A toward the center of the one long side of the first conductive film 10A, and the first terminal wiring pattern 38A is connected electrically to the corresponding first terminal 116A. Thus, the first terminal wiring patterns 38A, which are connected to each pair of the corresponding first wire connections 36A formed on the right and left of the one long side of the sensing region 112, have approximately the same length. Of course, the first terminals 116A may be formed in a corner of the first conductive film 10A or in the vicinity thereof. However, in this case, the difference in length between the longest first terminal wiring pattern 38A and the shortest first terminal wiring pattern 38A is increased, such that the longest first terminal wiring pattern 38A and the first terminal wiring patterns 38A in the vicinity thereof tend to become disadvantageously poor in the rate at which signals are transferred therefrom to the corresponding first conductive patterns 20A. Thus, in the present embodiment, the first terminals 116A are formed in a longitudinal center of the one long side of the first conductive film 10A, whereby deterioration in the transfer rate of local signals is prevented, and the response speed is increased.

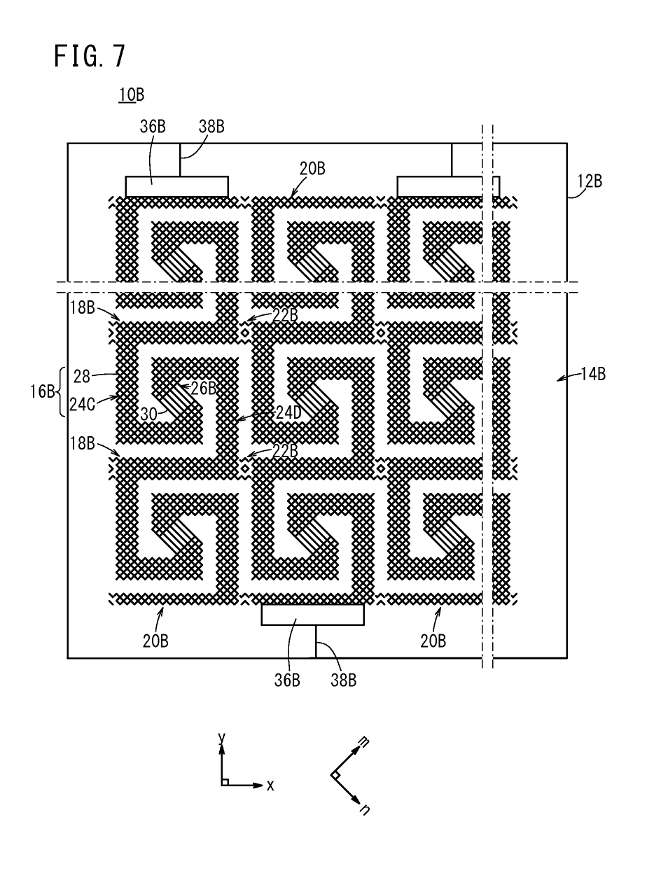

As shown in FIGS. 6A and 7, the second conductive film 10B includes a second conductive part 14B, which is formed on one main surface of a second transparent substrate 12B. The second conductive part 14B contains two or more second conductive patterns 20B with second dummy patterns 22B disposed therebetween. Each of the second conductive patterns 20B is composed of thin metal wires and contains a plurality of second pad portions 16B, which are connected with each other by a second connection 18B. Each of the second dummy patterns 22B is composed of thin metal wires, which is not connected to the second conductive patterns 20B.

Two or more second pad portions 16B are arranged in the y direction (second direction) with the second connection 18B disposed therebetween so as to form the second conductive pattern 20B. Two or more second conductive patterns 20B are arranged in the x direction (the first direction).

The second pad portion 16B includes a third spiral 24C extending from one second connection 18B, a fourth spiral 24D extending from the opposite second connection 18B, and a second linkage 26B that links the third spiral 24C and the fourth spiral 24D. The third spiral 24C, the fourth spiral 24D, and the second connection 18B each contain a combination made up of a plurality of lattices 28. The second linkage 26B contains a plurality of conductive wires 30.

The side length of the second pad portion 16B preferably is 3 to 10 mm, and more preferably, is 4 to 6 mm, similar to the case of the first conductive patterns 20A. The side length of the lattice 28 in the second pad portion 16B preferably is 100 to 400 μm, more preferably, is 150 to 300 μm, and most preferably, is 210 to 250 μm. The line width of the lattice 28, i.e. the thin metal wire, is 1 to 15 μm.

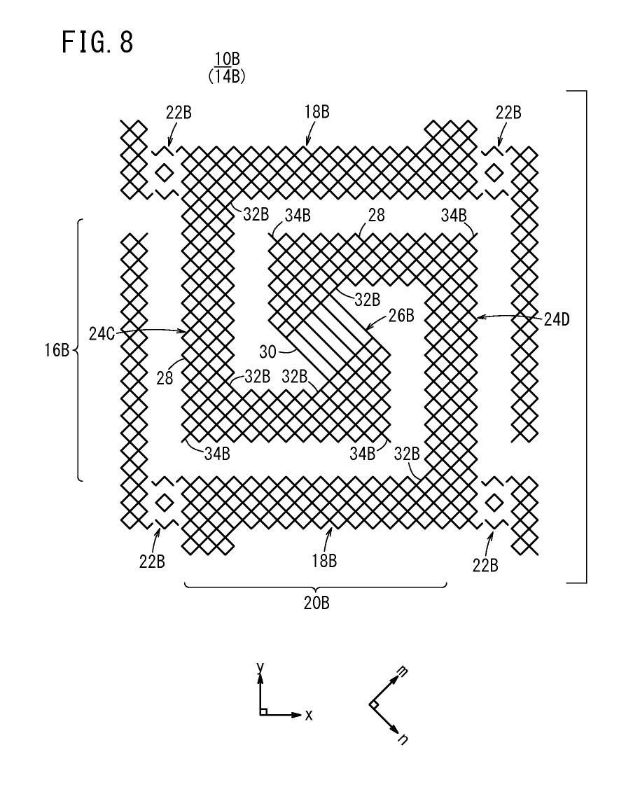

As shown in FIG. 8, edges of the third spiral 24C and the fourth spiral 24D each have a concavo-convex shape having peaks and troughs at the vertices of the lattices 28. The lattices 28 may be arranged in the following manner, for example, to form the concavo-convex shape. In the third spiral 24C, five lattices 28 are arranged in the third direction (the m direction) to form an array. A plurality of such arrays are arranged from one of the second connections 18B toward another of the second connections 18B, and further are arranged in the first direction (the x direction) from a corner of the third spiral 24C. In particular, on a side adjacent to the second linkage 26B (at the end of the third spiral 24C), eleven lattices 28 are arranged in the third direction. Ten lattices 28 are arranged in the third direction adjacent to the eleven lattices 28, and eight lattices, six lattices, four lattices, and two lattices are further arranged sequentially in the first direction. Thus, the number of lattices 28 is reduced by 2 in the first direction.

The fourth spiral 24D has a similar structure. In the fourth spiral 24D, five lattices 28 are arranged in the third direction (the m direction) so as to form an array. A plurality of such arrays are arranged from the other of the second connections 18B toward the one of the second connections 18B, and further are arranged in the first direction from a corner of the fourth spiral 24D. On a side adjacent to the second linkage 26B (at the end of the fourth spiral 24D), eleven lattices 28 are arranged in the third direction. Ten lattices 28 are arranged in the third direction adjacent to the eleven lattices 28, and eight lattices, six lattices, four lattices, and two lattices are further arranged sequentially in the first direction. Thus, the number of lattices 28 is reduced by 2 in the first direction. The number of lattices 28 in the second pad portion 16B is greater than the number of lattices 28 in the first pad portion 16A.

It should be understood that, although in the above description, the arrangement of the lattices 28 is described mainly in relation to the third direction, the arrangement can be described in relation to the fourth direction, or in relation to a combination of the third and fourth directions.

Two or more second long sides 32B and second protrusions 34B are formed on the edges of the third spiral 24C and the fourth spiral 24D. The second long side 32B is formed by arranging the sides of the lattices 28 adjacently along a straight line. The second protrusion 34B is composed of a thin metal wire that extends perpendicularly from at least one of the second long sides 32B. More specifically, on the edges of the third spiral 24C and the fourth spiral 24D, the second long sides 32B are formed on the inside of the corners thereof, and the second protrusions 34B of the thin metal wires are formed on the outside of the corners thereof.

For example, the second linkage 26B contains six straight conductive wires 30 that extend in the fourth direction. In the example of FIGS. 7 and 8, the length of the conductive wire 30 is 4 times greater than the side length of the lattice 28. The length of the conductive wire 30 depends on the distance between the third spiral 24C and the fourth spiral 24D, and may be an integral multiple of the side length of the lattice 28. The direction in which the conductive wires 30 extend is not limited to the fourth direction, and may be selected from the first direction, the second direction, the third direction, or the like, depending on the positions of the ends of the third spiral 24C and the fourth spiral 24D.

The second dummy patterns 22B are formed between two adjacent second conductive patterns 20B. More specifically, each of the second dummy patterns 22B is disposed between the second connection 18B of one of the second conductive patterns 20B and the second connection 18B of another of the second conductive patterns 20B. In the example of FIG. 8, the second dummy pattern 22B is disposed such that the second connections 18B are connected by the lattices 28 (for example, by arranging three lattices 28 in each of the first and second directions, the vertices being arranged adjacent to each other), and in the connection, certain ones of the thin metal wires are removed from the lattices 28. For example, the thin metal wires around the central lattice 28 and the thin metal wires in the vicinity of the end of the second connection 18B are removed in order to form the second dummy pattern 22B. Thus, the second dummy pattern 22B contains the central lattice 28 and a plurality of wavy shapes containing lattice sides, such that the central lattice 28 is sandwiched between the wavy shapes.

For example, as shown in FIG. 5, one end of each of alternate odd-numbered second conductive patterns 20B, and an opposite end of each of even-numbered second conductive patterns 20B are open ends. Meanwhile, for example, at one end of each of the even-numbered second conductive patterns 20B and in the opposite end of each of the odd-numbered second conductive patterns 20B, ends of each of the second pad portions 16B are connected electrically by a second wire connection 36B to a second terminal wiring pattern 38B, which is composed of a thin metal wire.

A large number of the second conductive patterns 20B are arranged in the sensing region 112, and a plurality of the second terminal wiring patterns 38B, which extend from the second wire connections 36B, are arranged in the terminal wiring region 114.

As shown in FIG. 4, in the terminal wiring region 114, a plurality of second terminals 116B are arranged in the longitudinal center in the lengthwise direction of the periphery on one long side of the second conductive film 10B. For example, odd-numbered second wire connections 36B are arranged in a straight line in the x direction along one short side of the sensing region 112 (a short side closest to one short side of the second conductive film 10B), and even-numbered second wire connections 36B are arranged in a straight line in the x direction along the other short side of the sensing region 112 (a short side closest to another short side of the second conductive film 10B).

For example, each of the odd-numbered second conductive patterns 20B is connected to a corresponding odd-numbered second wire connection 36B, and each of the even-numbered second conductive patterns 20B is connected to a corresponding even-numbered second wire connection 36B. The second terminal wiring patterns 38B extend from the odd-numbered and the even-numbered second wire connections 36B to the center of one long side of the second conductive film 10B, and each of the odd-numbered and the even-numbered second wire connections 36B are connected electrically to the corresponding second terminals 116B. Thus, for example, the 1st and 2nd second terminal wiring patterns 38B have approximately the same length, and similarly the (2n−1)th and (2n)th second terminal wiring patterns 38B have approximately the same length (where n=1, 2, 3, . . . ).

It goes without saying that the second terminals 116B may be formed in a corner of the second conductive film 10B or in the vicinity thereof. However, in this case, as described above, the longest second terminal wiring pattern 38B and the second terminal wiring patterns 38B in the vicinity thereof are disadvantageously poor in the rate at which signals are transferred to the corresponding second conductive patterns 20B. Thus, in the present embodiment, the second terminals 116B are formed in the longitudinal center of the one long side of the second conductive film 10B, whereby deterioration in the local signal transfer rate is prevented, and the response speed is increased.

The first terminal wiring patterns 38A may be arranged in the same manner as described above with respect to the second terminal wiring patterns 38B. In addition, the second terminal wiring patterns 38B may be arranged in the same manner as described above with respect to the first terminal wiring patterns 38A.

In the case that the conductive film stack 50 is used in a touch panel, the protective layer is formed on the first conductive film 10A. In addition, the first terminal wiring patterns 38A, which extend from the first conductive patterns 20A in the first conductive film 10A, and the second terminal wiring patterns 38B, which extend from the second conductive patterns 20B in the second conductive film 10B, are connected to a scan control circuit or the like.

A self or mutual capacitance technology preferably is used for detecting the touch position. In self capacitance technology, a voltage signal for detecting the touch position is supplied sequentially to the first conductive patterns 20A, and further, a voltage signal for detecting the touch position is supplied sequentially to the second conductive patterns 20B. On the condition that a finger comes into contact with or close to the upper surface of the protective layer 106, the capacitance between the first conductive pattern 20A and the second conductive pattern 20B at the touch position and GND (ground) potential is increased, whereby signals from the first conductive pattern 20A and the second conductive pattern 20B exhibit waveforms that differ from those of the signals from the other conductive patterns. Thus, the touch position is calculated by a control circuit, based on the signals transmitted from the first conductive pattern 20A and the second conductive pattern 20B. On the other hand, in mutual capacitance technology, for example, a voltage signal for detecting the touch position is supplied sequentially to the first conductive patterns 20A, and the second conductive patterns 20B are subjected to sensing (transmitted signal detection) in a sequential manner. On the condition that a finger comes into contact with or close to the upper surface of the protective layer 106, a parallel stray capacitance of the finger is added to a parasitic capacitance between the first conductive pattern 20A and the second conductive pattern 20B at the touch position, whereby a signal from the second conductive pattern 20B exhibits a waveform that differs from those of the signals from the other second conductive patterns 20B. Thus, the touch position is calculated by a control circuit, based on the order of the first conductive pattern 20A, which is supplied with the voltage signal, and the signal transmitted from the second conductive pattern 20B. Using self or mutual capacitance technology, even on the condition that two fingers come into contact with or close to the upper surface of the protective layer 106 simultaneously, the touch positions can be detected. Conventional related detection circuits, which make use of projected capacitive technologies, are described in U.S. Pat. Nos. 4,582,955, 4,686,332, 4,733,222, 5,374,787, 5,543,588, and 7,030,860, and in U.S. Patent Application Publication No. 2004/0155871, etc.

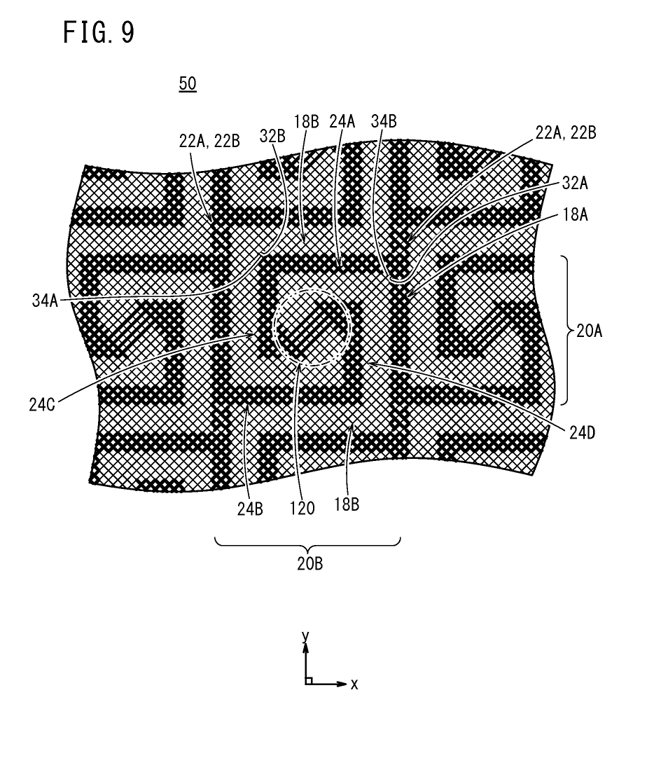

For example, on the condition that the first conductive film 10A is stacked on the second conductive film 10B to thereby form the conductive film stack 50, the first conductive patterns 20A and the second conductive patterns 20B are arranged as shown in FIG. 9. Although the first conductive patterns 20A and the second conductive patterns 20B are shown in an exaggerated manner by thick lines and thin lines, respectively, to clearly represent the positions thereof in FIG. 9, the line width of the first conductive patterns 20A and the second conductive patterns 20B is the same.

(1) The first linkage 26A in the first conductive pattern 20A (see FIG. 1) and the second linkage 26B in the second conductive pattern 20B (see FIG. 7) intersect in a substantially perpendicular manner. Combined pattern 120 of the first linkage 26A and the second linkage 26B contains a plurality of lattices 28.

(2) The second connection 18B in the second conductive pattern 20B is positioned between two adjacent first conductive patterns 20A, and the first connection 18A in the first conductive pattern 20A is positioned between two adjacent second conductive patterns 20B. In this case, at the boundary between the second connection 18B and the first conductive pattern 20A, vertices of the lattices 28 in the second connection 18B overlap with vertices of the lattices 28 in the first conductive patterns 20A, and the projected distances between the sides of the lattices 28 are approximately equal to the side length of the lattices 28, thereby providing a plurality of additional lattices 28. Additional lattices 28 also are arranged in the same manner at the boundary between the first connection 18A and the second conductive pattern 20B.

(3) The third spiral 24C or the fourth spiral 24D in the second conductive pattern 20B is positioned between the first spiral 24A and the second spiral 24B in the first conductive pattern 20A. In addition, the first spiral 24A or the second spiral 24B in the first conductive pattern 20A is positioned between the third spiral 24C and the fourth spiral 24D in the second conductive pattern 20B. In this case, at the boundary between the first spiral 24A and the third spiral 24C or the fourth spiral 24D, as well as at the boundary between the second spiral 24B and the third spiral 24C or the fourth spiral 24D, vertices of the lattices 28 in the first spiral 24A and the second spiral 24B overlap with vertices of the lattices 28 in the third spiral 24C or the fourth spiral 24D, and the projected distances between the sides of the lattices 28 are approximately equal to the side length of the lattices 28, thereby providing a plurality of additional lattices 28. Additional lattices 28 also are arranged in the same manner at the boundary between the third spiral 24C and the first spiral 24A or the second spiral 24B, and at the boundary between the fourth spiral 24D and the first spiral 24A or the second spiral 24B.

(4) The second connection 18B is positioned between two adjacent first dummy patterns 22A, which are arranged in the first direction (the x direction), and the first connection 18A is positioned between two adjacent second dummy patterns 22B, which are arranged in the second direction (the y direction). In this case, at the boundary between the first dummy pattern 22A and the second connection 18B, vertices of the lattices 28 in the first dummy pattern 22A overlap with vertices of the lattices 28 in the second connection 18B, and the projected distances between the sides of the lattices 28 are approximately equal to the side length of the lattices 28, thereby providing a plurality of additional lattices 28. Additional lattices 28 also are arranged in the same manner at the boundary between the second dummy pattern 22B and the first connection 18A.

(5) The first long side 32A that has the first protrusion 34A is arranged in facing relation to the second long side 32B that does not have the second protrusion 34B, and the first long side 32A that does not have the first protrusion 34A is arranged in facing relation to the second long side 32B that has the second protrusion 34B, thereby providing a plurality of additional lattices 28.

(6) The first dummy pattern 22A and the second dummy pattern 22B are arranged in facing relation to each other, such that defects (from which the thin metal wires have been removed) in the first dummy pattern 22A are compensated for by the thin metal wires in the second dummy patterns 22B, and defects (from which the thin metal wires have been removed) in the second dummy pattern 22B are compensated for by the thin metal wires in the first dummy pattern 22A, thereby providing a plurality of additional lattices 28.

As a result of using the above arrangement, a large number of lattices 28 are arranged over the entire surface, and boundaries between the first pad portions 16A and the second pad portions 16B, etc., can hardly be found.

In the case that each edge of the first spiral 24A to the fourth spiral 24D does not have a concavo-convex shape having peaks and troughs at the vertices of the lattices 28, but instead has a straight line shape formed by arranging the sides of the lattices 28 along a straight line, the straight line of the first spiral 24A overlaps with the straight line of the third spiral 24C or the fourth spiral 24D, and the straight line of the second spiral 24B overlaps with the straight line of the third spiral 24C or the fourth spiral 24D. However, the widths at the overlapping region of the straight lines are increased (i.e., thickened lines are formed) due to slight deterioration in positioning accuracy of the stack, such that the boundaries between the first pad portions 16A and the second pad portions 16B are made highly visible and thus visibility is deteriorated. In contrast, in the present embodiment, as described above, each edge of the first spiral 24A to the fourth spiral 24D has a concavo-convex shape having peaks and troughs at the vertices of the lattices 28, such that the boundaries between the first pad portions 16A and the second pad portions 16B are made less visible and thus visibility is improved.

In addition, in the case that each edge of the first spiral 24A to the fourth spiral 24D has a straight line shape formed by arranging the sides of the lattices 28 along a straight line, the straight line of the third spiral 24C or the fourth spiral 24D is positioned directly underneath the straight line of the first spiral 24A, and the straight line of the third spiral 24C or the fourth spiral 24D is positioned directly underneath the straight line of the second spiral 24B. In this case, all of the straight lines function as conductive portions, so that a parasitic capacitance is formed between the straight line of the first spiral 24A and the straight line of the third spiral 24C or the fourth spiral 24D, and between the straight line of the second spiral 24B and the straight line of the third spiral 24C or the fourth spiral 24D. The parasitic capacitance acts as noise on the charge information, such that the S/N ratio is significantly deteriorated. Furthermore, since the parasitic capacitance is formed between each pair of the first pad portion 16A and the second pad portion 16B, a large number of such parasitic capacitances are connected in parallel between the first conductive patterns 20A and the second conductive patterns 20B, thereby increasing the CR time constant. On the condition that the CR time constant is increased, there is a possibility that the waveform rise time of the voltage signal supplied to the first conductive pattern 20A (and the second conductive pattern 20B) will be delayed, and it is unlikely that the electric field required for position detection would be generated within the predetermined scan time. In addition, there is a possibility that the waveform rise or fall time of the signal transmitted from each of the first conductive patterns 20A and the second conductive patterns 20B will be delayed, such that a change in the waveform of the transmitted signal cannot be detected within the predetermined scan time. This leads to deterioration in detection accuracy and response speed. Thus, in this case, detection accuracy and response speed can be improved only by reducing the number of the first pad portions 16A and the second pad portions 16B (lowering resolution), or by reducing the size of the display screen, and the conductive film stack 50 cannot be used on a large screen such as a B5 sized screen, an A4 sized screen, or a larger screen.

In contrast, in the present embodiment, each edge of the first spiral 24A to the fourth spiral 24D has a concavo-convex shape having peaks and troughs at the vertices of the lattices 28. At the boundary between the first spiral 24A and the third spiral 24C or the fourth spiral 24D, and at the boundary between the second spiral 24B and the third spiral 24C or the fourth spiral 24D, the vertices of the lattices 28 in the first spiral 24A and the second spiral 24B overlap with the vertices of the lattices 28 in the third spiral 24C or the fourth spiral 24D, and the projected distance Lf between sides 28a of the lattices 28 (see FIG. 6A) is approximately equal to the side length of the lattices 28. Furthermore, only the ends of the first protrusions 34A in the first pad portions 16A overlap with the second long sides 32B in the second pad portions 16B, and only the ends of the second protrusions 34B in the second pad portions 16B overlap with the first long sides 32A in the first pad portions 16A. Therefore, only a small parasitic capacitance is formed between the first pad portion 16A and the second pad portion 16B. As a result, the CR time constant can be reduced, thereby improving detection accuracy and response speed.

Preferably, the optimum value of the projected distance Lf is determined appropriately depending not on the sizes of the first pad portions 16A and the second pad portions 16B, but on the sizes (the line widths and the side lengths) of the lattices 28 in the first pad portions 16A and the second pad portions 16B. On the condition that the lattices 28 have an excessively large size as compared with the sizes of the first pad portions 16A and the second pad portions 16B, light transmittance may be improved, but the dynamic range of the transmitted signal becomes reduced, leading to a decrease in detection sensitivity. On the other hand, on the condition that the lattices 28 have an excessively small size, the detection sensitivity may be improved, but light transmittance becomes deteriorated under the restriction of line width reduction.

On the condition that the lattices 28 have a line width of 1 to 15 μm, the optimum value of the projected distance Lf (the optimum distance) preferably is 100 to 400 μm, and more preferably, is 200 to 300 μm. In the case that the lattices 28 have a smaller line width, the optimum distance can be further reduced. However, in this case, electrical resistance may be increased, and even under a small parasitic capacitance, the CR time constant may be increased, thereby leading to deterioration in detection sensitivity and response speed. Thus, the line width of the lattices 28 preferably remains within the above range.

For example, the sizes of the first pad portions 16A, the second pad portions 16B, and the lattices 28 are determined based on the size of the display panel 110, or the sensing region 112 and the touch position detection resolution (drive pulse period). In addition, an optimum value of the projected distance Lf between the sides 28a of the lattices 28 is obtained based on the line width of the lattice 28.

In the present embodiment, in the terminal wiring region 114, a plurality of first terminals 116A are formed in the longitudinal center of the periphery on one long side of the first conductive film 10A, and a plurality of second terminals 116B are formed in the longitudinal center of the periphery on one long side of the second conductive film 10B. In particular, in the example of FIG. 4, the first terminals 116A and the second terminals 116B are arranged in close proximity without overlapping each other, and the first terminal wiring patterns 38A and the second terminal wiring patterns 38B do not overlap vertically with each other. For example, the first terminal 116A may partially overlap with the odd-numbered second terminal wiring pattern 38B.

Thus, the first terminals 116A and the second terminals 116B can be connected electrically to the control circuit using a cable and two connectors (a connector for the first terminals 116A and a connector for the second terminals 116B), or one connector (a complex connector for the first terminals 116A and the second terminals 116B).

Since the first terminal wiring patterns 38A and the second terminal wiring patterns 38B do not vertically overlap with each other, parasitic capacitance is reduced between the first terminal wiring patterns 38A and the second terminal wiring patterns 38B, and deterioration in the response speed is prevented.

Since the first wire connections 36A are arranged along one long side of the sensing region 112, and the second wire connections 36B are arranged along both short sides of the sensing region 112, the area of the terminal wiring region 114 can be reduced. Therefore, the size of the display panel 110, which contains the touch panel 100, can easily be reduced, and the display screen 110a can be made to seem larger. Also, operability of the touch panel 100 can be improved.

The area of the terminal wiring region 114 may further be reduced by reducing the distance between the adjacent first terminal wiring patterns 38A, or by reducing the distance between the adjacent second terminal wiring patterns 38B. In this case, the distance preferably is 10 to 50 μm in view of preventing migration.

Alternatively, the area of the terminal wiring region 114 may be reduced by arranging the second terminal wiring pattern 38B between the adjacent first terminal wiring patterns 38A, as viewed from above. However, on the condition that the pattern becomes misaligned, the first terminal wiring pattern 38A may overlap vertically with the second terminal wiring pattern 38B, thereby increasing parasitic capacitance therebetween, which leads to deterioration in the response speed. Thus, in the case that such an arrangement is used, the distance between the adjacent first terminal wiring patterns 38A preferably is 50 to 100 μm.

Consequently, on the condition that the conductive film stack 50 is used in a projected capacitive touch panel 100 or the like, the response speed and the size of the touch panel 100 can easily be increased. Furthermore, boundaries between the first pad portions 16A of the first conductive film 10A and the second pad portions 16B of the second conductive film 10B can be made less visible, and a plurality of lattices 28 can be formed as a result of the combination of the first linkages 26A and the second linkages 26B, and the combination of the first dummy patterns 22A and the second dummy patterns 22B. Therefore, defects such as localized line thickening can be prevented, and overall visibility can be improved.

In addition, a large number of the first conductive patterns 20A and the second conductive patterns 20B can have a significantly reduced CR time constant, whereby the response speed can be increased, and detection of the position can readily be carried out within a given operation time (scan time). Thus, the screen size (i.e., the length or width, but not the thickness) of the touch panel 100 can easily be increased.

The number of the lattices 28 in the second pad portions 16B is larger than the number of the lattices 28 in the first pad portions 16A. Therefore, for example, in self capacitance technology, although the second pad portions 16B are positioned at a longer distance from the position at which the first pad portions 16A is touched, the second pad portions 16B can store a large amount of signal charge in the same manner as the first pad portions 16A, and the second conductive film 10B can exhibit a detection sensitivity approximately equal to that of the first conductive film 10A. Thus, the signal processing burden can be reduced, and detection accuracy can be improved.

For example, in mutual capacitance technology, the signal charges, which are stored in the second pad portions 16B that contain a larger number of the lattices 28, are read. Therefore, the output dynamic range to input can be increased, and the S/N ratio of the detection signal can be improved, together with improving detection sensitivity and detection accuracy.

In the above conductive film stack 50, as shown in FIGS. 5 and 6A, the first conductive part 14A is formed on one main surface of the first transparent substrate 12A, whereas the second conductive part 14B is formed on one main surface of the second transparent substrate 12B. Alternatively, as shown in FIG. 6B, the first conductive part 14A may be formed on one main surface of the first transparent substrate 12A, whereas the second conductive part 14B may be formed on another main surface of the first transparent substrate 12A. In this case, the second transparent substrate 12B is not used. The first transparent substrate 12A is stacked on the second conductive part 14B, and the first conductive part 14A is stacked on the first transparent substrate 12A. In addition, another layer may be disposed between the first conductive film 10A and the second conductive film 10B. As long as the first conductive part 14A and the second conductive part 14B are electrically insulated, the first conductive part 14A and the second conductive part 14B may be arranged in facing relation to each other.

As shown in FIG. 4, first alignment marks 118a and second alignment marks 118b preferably are formed on the corners, etc., of the first conductive film 10A and the second conductive film 10B. The first alignment marks 118a and the second alignment marks 118b are used for positioning the films during the process of bonding the films. In the case of bonding the first conductive film 10A and the second conductive film 10B to obtain the conductive film stack 50, the first alignment marks 118a and the second alignment marks 118b form composite alignment marks. Such composite alignment marks may be used for positioning the conductive film stack 50 during the process of attaching the conductive film stack 50 to the display panel 110.

Although in the above examples, the first conductive film 10A and the second conductive film 10B are used in the projected capacitive touch panel 100, the first conductive film 10A and the second conductive film 10B can be used in a surface capacitive touch panel or a resistive touch panel.

Although in the above examples, the conductive film stack 50 is produced by stacking the first conductive film 10A on the second conductive film 10B, the conductive film stack 50 may also be produced by stacking the second conductive film 10B on the first conductive film 10A.

The number of lattices 28 in the first pad portion 16A may be equal to the number of lattices 28 in the second pad portion 16B.

The second protrusion 34B may be formed on each of the second long sides 32B in the second pad portion 16B, without the first protrusions 34A being formed in the first pad portion 16A. Conversely, the first protrusion 34A may be formed on each of the first long sides 32A in the first pad portion 16A, without the second protrusions 34B being formed in the second pad portion 16B.

The first conductive patterns 20A and the second conductive patterns 20B may be formed as follows. For example, a photosensitive material having the first transparent substrate 12A or the second transparent substrate 12B with a photosensitive silver halide-containing emulsion layer provided thereon may be exposed and developed, whereby metallic silver portions and light-transmitting portions are formed in the exposed areas and the unexposed areas, respectively, in order to obtain the first conductive patterns 20A or the second conductive patterns 20B. The metallic silver portions may be subjected to at least one of a physical development treatment and a plating treatment in order to deposit a conductive metal thereon.

As shown in FIG. 6B, the first conductive patterns 20A may be formed on the one main surface of the first transparent substrate 12A, and the second conductive patterns 20B may be formed on another main surface thereof. In a typical method, in the case that the one main surface is exposed and the other main surface is exposed thereafter, situations occur occasionally in which desired first conductive patterns 20A and second conductive patterns 20B cannot be obtained. In particular, it is difficult for the first dummy patterns 22A, the second dummy patterns 22B, the first linkages 26A, the second linkages 26B, the first protrusions 34A, and the second protrusions 34B, etc., to be formed in a uniform manner.

Therefore, the following production method can preferably be used.

The first conductive patterns 20A on the one main surface and the second conductive patterns 20B on the other main surface can be formed by subjecting the photosensitive silver halide emulsion layers on either side of the first transparent substrate 12A to one-shot exposure.

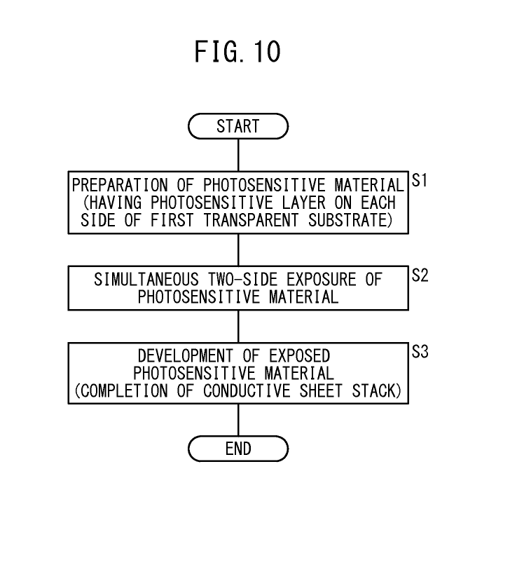

A specific example of the production method will be described below with reference to FIGS. 10 to 12.

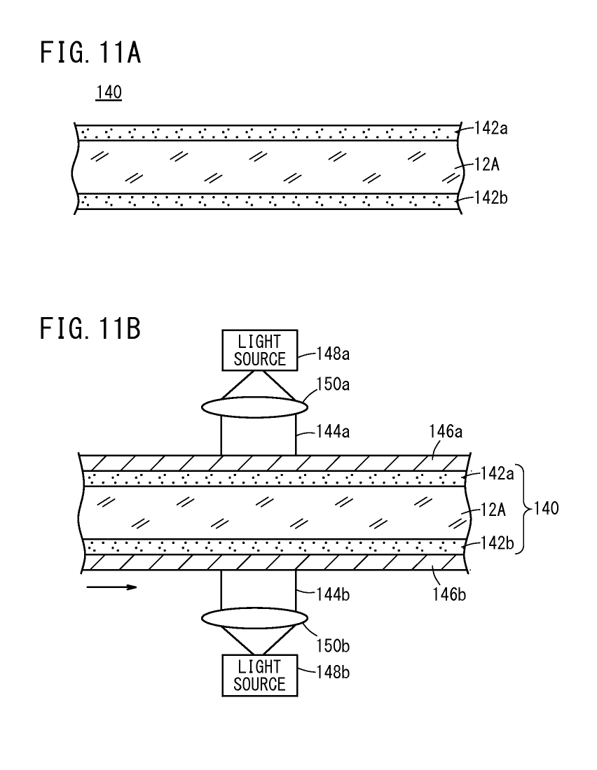

First, in step S1 of FIG. 10, an elongate photosensitive material 140 is prepared. As shown in FIG. 11A, the photosensitive material 140 includes the first transparent substrate 12A, a photosensitive silver halide emulsion layer formed on one main surface of the first transparent substrate 12A (hereinafter referred to as a first photosensitive layer 142a), and a photosensitive silver halide emulsion layer formed on another main surface of the first transparent substrate 12A (hereinafter referred to as a second photosensitive layer 142b).

In step S2 of FIG. 10, the photosensitive material 140 is exposed. During the exposure step, simultaneous two-side exposure is carried out, which includes a first exposure treatment for irradiating the first photosensitive layer 142a on the first transparent substrate 12A with light in a first exposure pattern, and a second exposure treatment for irradiating the second photosensitive layer 142b on the first transparent substrate 12A with light in a second exposure pattern. In the example of FIG. 11B, the first photosensitive layer 142a is irradiated with first light 144a (parallel light) through a first photomask 146a, and the second photosensitive layer 142b is irradiated with second light 144b (parallel light) through a second photomask 146b, while the long photosensitive material 140 is conveyed in one direction. The first light 144a is composed of light from a first light source 148a, which is converted into parallel light by an intermediate first collimator lens 150a. Similarly, the second light 144b is composed of light from a second light source 148b, which is converted into parallel light by an intermediate second collimator lens 150b. Although two light sources (the first light source 148a and the second light source 148b) are used in the example of FIG. 11B, only one light source may be used. In this case, light from the light source may be divided by an optical system into the first light 144a and the second light 144b, which are used for exposing the first photosensitive layer 142a and the second photosensitive layer 142b.

In step S3 of FIG. 10, the exposed photosensitive material 140 is developed in order to prepare the conductive film stack 50 shown in FIG. 6B. The conductive film stack 50 includes the first transparent substrate 12A, the first conductive part 14A (having the first conductive patterns 20A, etc.), which is formed in the first exposure pattern on the one main surface of the first transparent substrate 12A, and the second conductive part 14B (having the second conductive patterns 20B, etc.), which is formed in the second exposure pattern on the other main surface of the first transparent substrate 12A. Preferred ranges for the exposure time and development time for the first photosensitive layer 142a and the second photosensitive layer 142b cannot be determined categorically, and depend on the types of the first light source 148a, the second light source 148b, and a developer, etc. The exposure time and development time may be selected in view of achieving a development ratio of 100%.

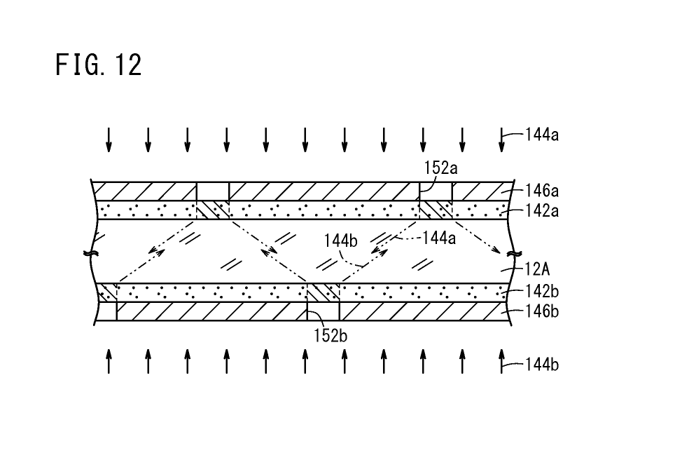

As shown in FIG. 12, during the first exposure treatment in the production method according to the present embodiment, for example, the first photomask 146a is placed in intimate contact with the first photosensitive layer 142a, the first light source 148a is arranged in facing relation to the first photomask 146a, and the first light 144a is emitted from the first light source 148a toward the first photomask 146a, so that the first photosensitive layer 142a is exposed. The first photomask 146a includes a glass substrate composed of transparent soda glass, and a mask pattern (a first exposure pattern 152a) is formed on the first photomask 146a. Therefore, during the first exposure treatment, areas in the first photosensitive layer 142a, which correspond to the first exposure pattern 152a in the first photomask 146a, are exposed. A space of approximately 2 to 10 μm may be formed between the first photosensitive layer 142a and the first photomask 146a.

Similarly, during the second exposure treatment, for example, the second photomask 146b is placed in intimate contact with the second photosensitive layer 142b, the second light source 148b is arranged in facing relation to the second photomask 146b, and the second light 144b is emitted from the second light source 148b toward the second photomask 146b, so that the second photosensitive layer 142b is exposed. In the same manner as the first photomask 146a, the second photomask 146b includes a glass substrate composed of transparent soda glass, and a mask pattern (a second exposure pattern 152b) is formed on the second photomask 146b. Therefore, during the second exposure treatment, areas in the second photosensitive layer 142b, which correspond to the second exposure pattern 152b in the second photomask 146b, are exposed. In this case, a space of approximately 2 to 10 μm may be formed between the second photosensitive layer 142b and the second photomask 146b.

During the first and second exposure treatments, emission of the first light 144a from the first light source 148a and emission of the second light 144b from the second light source 148b may be carried out simultaneously or independently. In the case that such emissions are carried out simultaneously, the first photosensitive layer 142a and the second photosensitive layer 142b can be exposed simultaneously in one exposure process, thereby reducing the treatment time.

In the case that both of the first photosensitive layer 142a and the second photosensitive layer 142b are not spectrally sensitized, during two-side exposure of the photosensitive material 140, light incident on one side may affect image formation on the other side (the back side).

Thus, the first light 144a from the first light source 148a reaches the first photosensitive layer 142a, and is scattered by silver halide particles in the first photosensitive layer 142a. A portion of the scattered light is transmitted through the first transparent substrate 12A and reaches the second photosensitive layer 142b. Then, a large area of the boundary between the second photosensitive layer 142b and the first transparent substrate 12A is exposed in order to form a latent image. As a result, the second photosensitive layer 142b is exposed to the second light 144b from the second light source 148b and the first light 144a from the first light source 148a. Upon developing of the second photosensitive layer 142b to prepare the conductive film stack 50, the conductive pattern corresponding to the second exposure pattern 152b (the second conductive part 14B) is formed, while in addition, due to the first light 144a from the first light source 148a, a thin conductive layer is formed between the conductive pattern, such that a desired pattern (corresponding to the second exposure pattern 152b) cannot be obtained. Such a feature also holds true for the first photosensitive layer 142a.

As a result of intensive research with a view toward solving such problems, it has been found that on the condition that the thickness and the applied silver amount of the first photosensitive layer 142a and the second photosensitive layer 142b are controlled within particular ranges, incident light can be absorbed by the silver halide to thereby suppress transmission of light to the back side. In the present embodiment, the thickness of the first photosensitive layer 142a and the second photosensitive layer 142b may be 1 to 4 μm, and the upper limit thereof preferably is 2.5 μm. The applied silver amount of the first photosensitive layer 142a and the second photosensitive layer 142b may be 5 to 20 g/m².

In the above described contact two-side exposure technology, exposure may be inhibited by dust or the like that becomes attached to the film surface, thereby generating image defects. It is known that attachment of dust can be prevented by applying a conductive substance such as a metal oxide or a conductive polymer to the film. However, a metal oxide or the like remains in the processed product, which tends to deteriorate the transparency of the final product, and a conductive polymer is disadvantageous in terms of storage stability, etc. As a result of intensive research, it has been found that a silver halide layer with a reduced binder content exhibits satisfactory conductivity and prevents static charge. Thus, the silver/binder volume ratio should be controlled in the first photosensitive layer 142a and the second photosensitive layer 142b. The silver/binder volume ratio of the first photosensitive layer 142a and the second photosensitive layer 142b is 1/1 or greater, and preferably, is 2/1 or greater.

In the case that the thicknesses, the applied silver amounts, and the silver/binder volume ratios of the first photosensitive layer 142a and the second photosensitive layer 142b are selected and controlled as described above, as shown in FIG. 12, the first light 144a, which is emitted from the first light source 148a toward the first photosensitive layer 142a, does not reach the second photosensitive layer 142b. Similarly, the second light 144b, which is emitted from the second light source 148b toward the second photosensitive layer 142b, does not reach the first photosensitive layer 142a. As a result, in a subsequent development process for producing the conductive film stack 50, as shown in FIG. 6B, only the conductive pattern corresponding to the first exposure pattern 152a (the pattern of the first conductive part 14A) is formed on the one main surface of the first transparent substrate 12A, and only the conductive pattern corresponding to the second exposure pattern 152b (the pattern of the second conductive part 14B) is formed on the other main surface of the first transparent substrate 12A, so that desired patterns can be obtained.

In the production method, which uses the aforementioned one-shot two-side exposure technique, the first photosensitive layer 142a and the second photosensitive layer 142b are capable of exhibiting both satisfactory conductivity and two-side exposure suitability. By exposure thereof, the same or different patterns can be formed on respective surfaces of a single first transparent substrate 12A, whereby the electrodes of the touch panel 100 can be formed easily, and the touch panel 100 can be made thinner (smaller) in scale.

In the above-described production method, the first conductive patterns 20A and the second conductive patterns 20B are formed using photosensitive silver halide emulsion layers. Other production methods for the first conductive patterns 20A and the second conductive patterns 20B may include the following methods.

A photoresist film on a copper foil disposed on the first transparent substrate 12A or the second transparent substrate 12B may be exposed and developed in order to form a resist pattern. Further, the copper foil exposed from the resist pattern may be etched in order to form the first conductive patterns 20A and the second conductive patterns 20B.

Alternatively, a paste containing fine metal particles may be printed on the first transparent substrate 12A or the second transparent substrate 12B, and the printed paste may be plated with a metal in order to form the first conductive patterns 20A and the second conductive patterns 20B.

The first conductive patterns 20A and the second conductive patterns 20B may be printed on the first transparent substrate 12A or the second transparent substrate 12B using screen printing or a gravure printing plate.

The first conductive patterns 20A and the second conductive patterns 20B may also be formed on the first transparent substrate 12A or the second transparent substrate 12B using an inkjet printing method.

A particularly preferred method primarily will be described below, which involves a process of using a photographic photosensitive silver halide material for producing the first conductive film 10A and the second conductive film 10B according to the present embodiment.

The method for producing the first conductive film 10A and the second conductive film 10B according to the present embodiment includes the following three processes, depending on the photosensitive materials and the development treatments used.

(1) A process comprising subjecting a photosensitive black-and-white silver halide material free of physical development nuclei to a chemical or thermal development treatment, to thereby form metallic silver portions on the material.

(2) A process comprising subjecting a photosensitive black-and-white silver halide material having a silver halide emulsion layer containing physical development nuclei to a solution physical development treatment, to thereby form metallic silver portions on the material.

(3) A process comprising subjecting a stack of a photosensitive black-and-white silver halide material free of physical development nuclei and an image-receiving sheet having a non-photosensitive layer containing physical development nuclei to a diffusion transfer development treatment, to thereby form metallic silver portions on the non-photosensitive image-receiving sheet.

In process (1), an integral black-and-white development procedure is used to form a transmittable conductive film such as a light-transmitting conductive film on the photosensitive material. The resulting silver is chemically or thermally developed silver containing a high-specific surface area filament, and thereby shows a high activity in the following plating or physical development treatment.

In process (2), silver halide particles are melted around the physical development nuclei and deposited on the nuclei in the exposed areas, to thereby form a transmittable conductive film, such as a light-transmitting conductive film, on the photosensitive material. Also, in this process, an integral black-and-white development procedure is used. Although high activity can be achieved since the silver halide is deposited on the physical development nuclei during development, the developed silver has a spherical shape with a small specific surface.

In process (3), the silver halide particles are melted in unexposed areas, and diffused and deposited on the development nuclei of the image-receiving sheet, to thereby form a transmittable conductive film, such as a light-transmitting conductive film, on the sheet. In this process, a so-called separation-type procedure is used, and the image-receiving sheet is peeled off from the photosensitive material.

A negative or reversal development treatment can be used in any of the foregoing processes. In diffusion transfer development, the negative development treatment can be carried out using an auto-positive photosensitive material.

The chemical development, thermal development, solution physical development, and diffusion transfer development have the meanings generally known in the art, and are explained in common photographic chemistry texts such as Shinichi Kikuchi, “Shashin Kagaku (Photographic Chemistry)”, Kyoritsu Shuppan Co., Ltd., 1955, and C. E. K. Mees, “The Theory of Photographic Processes, 4th ed.”, McMillan, 1977. A liquid treatment generally is used in the present invention, and a thermal development treatment can also be utilized. For example, the techniques described in Japanese Laid-Open Patent Publication Nos. 2004-184693, 2004-334077, and 2005-010752, and Japanese Patent Application Nos. 2004-244080 and 2004-085655 can be used in the present invention.

An explanation shall now be given in relation to the structures of each of the layers in the first conductive film 10A and the second conductive film 10B according to the present embodiment.

### [First Transparent Substrate 12A, Second Transparent Substrate 12B]

Plastic films, plastic plates, glass plates, or the like, can be given as examples of materials to be used as the first transparent substrate 12A and the second transparent substrate 12B.

As materials for the aforementioned plastic film and the plastic plate, there can be used, for example, polyesters such as polyethylene terephthalates (PET) and polyethylene naphthalates (PEN), etc., polyolefins such as polyethylenes (PE), polypropylenes (PP), polystyrenes, and EVA, etc., vinyl resins, and apart therefrom, polycarbonates (PC), polyamides, polyimides, acrylic resins, and triacetyl celluloses (TAC), etc.

As materials for the first transparent substrate 12A and the second transparent substrate 12B, preferably, plastic films or plastic plates having a melting point less than or equal to approximately 290° C., are used, for example, PET (melting point 258° C.), PEN (melting point 269° C.), PE (melting point 135° C.), PP (melting point 163° C.), polystyrene (melting point 230° C.), polyvinyl chloride (melting point 180° C.), polyvinylidene chloride (melting point 212° C.), and TAC (melting point 290° C.), etc. From the standpoints of light transmittance and workability, etc., PET is particularly preferred. Since transparency is demanded for the conductive film, such as the first conductive film 10A or the second conductive film 10B used in the conductive film stack 50, preferably, a high degree of transparency is provided for the first transparent substrate 12A and the second transparent substrate 12B.

### [Silver Salt Emulsion Layer]

The silver salt emulsion layer that forms the conductive layer (conductive portions including the first pad portions 16A, the first connections 18A, the second pad portions 16B, the second connections 18B, and the lattices 28) in the first conductive film 10A and the second conductive film 10B contains a silver salt and a binder, and may further contain additives such as solvents and dyes in addition to the silver salt and the binder.

The silver salt used in the present embodiment may be an inorganic silver salt such as a silver halide or an organic silver salt such as silver acetate or the like. In the present embodiment, preferably, silver halide is used, which has excellent light sensing properties.

The applied silver amount (the amount of applied silver salt in terms of silver density) of the silver salt emulsion layer preferably is 1 to 30 g/m², more preferably, is 1 to 25 g/m², and still more preferably, is 5 to 20 g/m². In a case where the applied silver amount lies within the above-described range, the resultant conductive film stack 50 can exhibit a desired surface resistance.

As examples of binders that are used in the present embodiment, there may be used, for example, gelatins, polyvinyl alcohols (PVA), polyvinyl pyrolidones (PVP), polysaccharides such as starches, celluloses and derivatives thereof, polyethylene oxides, polyvinylamines, chitosans, polylysines, polyacrylic acids, polyalginic acids, polyhyaluronic acids, and carboxycelluloses. The binders exhibit neutral, anionic, or cationic properties depending on the ionic properties of the functional group.

In the present embodiment, the amount of the binder in the silver salt emulsion layer is not particularly limited, and may be selected appropriately in order to obtain properties of sufficient dispersion and adhesion. The volume ratio of silver/binder in the silver salt emulsion layer preferably is 1/4 or greater, and more preferably, is 1/2 or greater. The silver/binder volume ratio preferably is 100/1 or less, and more preferably, is 50/1 or less. In particular, the silver/binder volume ratio is more preferably 1/1 to 4/1, and most preferably, is 1/1 to 3/1. By maintaining the silver/binder volume ratio of the silver salt emulsion layer within such ranges, even under various applied silver amounts, variation in resistance can be reduced, and a conductive film stack 50 having uniform surface resistance can be obtained. Incidentally, the silver/binder volume ratio can be determined by converting the silver halide/binder weight ratio of the materials into a silver/binder weight ratio, and furthermore, by converting the silver/binder weight ratio into a silver/binder volume ratio.

### <Solvents>

The solvents used for forming the silver salt emulsion layer are not particularly limited, and examples thereof include water, organic solvents (e.g. alcohols such as methanol, ketones such as acetone, amides such as formamide, sulfoxides such as dimethyl sulfoxide, esters such as ethyl acetate, and ethers), ionic liquids, and mixtures of such solvents.

In the present embodiment, the ratio of the solvent to the total mass of the silver salt, the binder, etc., in the silver salt emulsion layer is 30% to 90% by mass, and preferably, is 50% to 80% by mass.

### <Other Additive Agents>

The additives used in the present embodiment are not particularly limited, and preferably, may be selected from among known additives.

### [Other Layer Structures]

A non-illustrated protective layer may be formed on the silver salt emulsion layer. In the present embodiment, the term “protective layer” implies a layer that contains a binder such as a gelatin or a high-molecular polymer, which is disposed on the photosensitive silver salt emulsion layer in order to improve mechanical properties and resistance to scratching. The thickness of the protective layer preferably is 0.5 μm or less. The method of applying or forming the protective layer is not particularly limited, and may be selected appropriately from among known application or forming methods. In addition, an undercoat layer or the like may be formed underneath the silver salt emulsion layer.

Next, respective steps of a method for producing the first conductive film 10A and the second conductive film 10B will be described.

### [Exposure]

In the present embodiment, although a case has been described in which the first conductive patterns 20A and the second conductive patterns 20B are implemented by means of a printing process, apart from a printing process, the first conductive patterns 20A and the second conductive patterns 20B may be formed by exposure and development treatments, etc. More specifically, a photosensitive material having the first transparent substrate 12A or the second transparent substrate 12B, together with the silver salt-containing layer or a photosensitive material coated with a photolithographic photopolymer provided thereon, is subjected to an exposure treatment. Exposure can be carried out by way of electromagnetic waves. For example, the electromagnetic waves may be constituted from light such as visible light or ultraviolet light, or rays of radiation such as X-rays or the like. Exposure may be carried out using a light source having a wavelength distribution or a specific wavelength.

### [Development Treatment]

In the present embodiment, after exposure of the emulsion layer, the emulsion layer is further subjected to a development treatment. The development treatment can be performed using common development treatment technologies for photographic silver salt films, photographic papers, print engraving films, emulsion masks for photomasking, and the like. Although not particularly limited, the developer used in the development treatment may be a PQ developer, an MQ developer, an MAA developer, etc. Examples of commercially available developers usable in the present invention include CN-16, CR-56, CP45X, FD-3, and PAPITOL available from FUJIFILM Corporation, C-41, E-6, RA-4, D-19, and D-72 available from Eastman Kodak Company, as well as developers contained in kits. Further, the developer may be a lith developer.

According to the present invention, the development process may include a fixation treatment for removing silver salt in unexposed areas in order to stabilize the material. Fixation treatment technologies for photographic silver salt films, photographic papers, print engraving films, emulsion masks for photomasking, and the like, may be used in the present invention.

In the fixation treatment, the fixation temperature preferably is approximately 20° C. to 50° C., and more preferably, is 25° C. to 45° C. The fixation time preferably is 5 seconds to 1 minute, and more preferably, is 7 seconds to 50 seconds. The amount of the fixer used preferably is 600 ml/m² or less, more preferably, is 500 ml/m² or less, and particularly preferably, is 300 ml/m² or less, per 1 m² of the photosensitive material treated.

The developed and fixed photosensitive material preferably is subjected to a water washing process or a stabilization treatment. The amount of water used in the water washing process or the stabilization treatment generally is 20 L or less, and may be 3 L or less, per 1 m² of the photosensitive material. The replenishment amount of the water may be zero, and thus the photosensitive material may be washed using a fixed amount of reserved water.

The ratio of the metallic silver contained in the exposed areas after development to the silver contained in such areas prior to exposure preferably is 50% or greater, and more preferably, is 80% or greater by mass. On the condition that the ratio is 50% or greater by mass, a high degree of conductivity can be achieved.

In the present embodiment, the tone (gradation) obtained following development is preferably in excess of 4.0, although no particular limit is placed thereon. In the case that the tone is greater than 4.0 following development, the conductivity of the conductive metal portion can be increased while maintaining high transmittance of the light-transmitting portion. For example, a tone of 4.0 or greater can be obtained by doping with rhodium or iridium ions.

The conductive film is obtained by carrying out the above steps. The surface resistance of the resultant conductive film preferably is within a range of 0.1 to 100 ohm/sq. The lower limit preferably is 1 ohm/sq, and more preferably, is 10 ohm/sq. The upper limit preferably is 70 ohm/sq, and more preferably, is 50 ohm/sq or less. The conductive film may be subjected to a calender treatment following the development treatment in order to obtain a desired surface resistance.

### [Physical Development and Plating Treatments]

In the present embodiment, in order to improve the conductivity of the metallic silver portion formed by the above exposure and development treatments, conductive metal particles may be deposited on the metallic silver portion by at least one of a physical development treatment and a plating treatment. In the present invention, the conductive metal particles may be deposited on the metallic silver portion by only one of the physical development and plating treatments or by a combination of such treatments. The metallic silver portion, which is subjected to at least one of a physical development treatment and a plating treatment in this manner, may also be referred to as a “conductive metal portion”.

In the present embodiment, the term “physical development” refers to a process in which metal ions such as silver ions are reduced by a reducing agent, whereby metal particles are deposited on a metal or metal compound core. Such physical development has been used in the fields of instant B&W film, instant slide film, printing plate production, etc., and similar technologies can be used in the present invention.

Physical development may be carried out at the same time as the above development treatment following exposure, or may be carried out separately after completion of the development treatment.

In the present embodiment, the plating treatment may contain electroless plating (such as chemical reduction plating or displacement plating), electrolytic plating, or a combination of both electroless plating and electrolytic plating. Known electroless plating technologies, for example, technologies used in printed circuit boards, etc., may be used in the present embodiment. Preferably, in the case of electroless plating, electroless copper plating is used.

### [Oxidation Treatment]

In the present embodiment, the metallic silver portion formed by the development treatment and the conductive metal portion, which is formed by at least one of the physical development treatment and the plating treatment, preferably is subjected to an oxidation treatment. For example, by the oxidation treatment, a small amount of metal deposited on the light-transmitting portion can be removed, so that the transmittance of the light-transmitting portion can be increased to roughly 100%.

### [Conductive Metal Portion]

In the present embodiment, the lower limit of the line width of the conductive metal portion (i.e., the thin metal wire) preferably is 1 μm or greater, 3 μm or greater, 4 μm or greater, or 5 μm or greater, whereas the upper limit thereof preferably is 15 μm or less, 10 μm or less, 9 μm or less, or 8 μm or less. On the condition that the line width is less than the lower limit, since the conductive metal portion has insufficient conductivity, in the case of being used as a touch panel, the detection sensitivity thereof also becomes insufficient. On the other hand, on the condition that the line width exceeds the upper limit, moiré patterns tend to become noticeable due to the conductive metal portion, and thus visibility may be worsened in the case of being used as a touch panel. On the condition that the line width is set within the above range, the occurrence of moiré patterns in the conductive metal portion is improved, and visibility is remarkably improved. The side length of the lattice 28 preferably is 100 to 400 μm, more preferably, is 150 to 300 μm, and most preferably, is 210 to 250 μm. Further, the conductive metal portion may have a part with a line width in excess of 200 μm for the purpose of providing a ground connection, etc.

In the present embodiment, from the standpoint of visible light transmittance, the opening ratio of the conductive metal portion preferably is 85% or greater, more preferably, is 90% or greater, and most preferably, is 95% or greater. The opening ratio is defined by the ratio of the light-transmitting portions (other than the first pad portions 16A, the first connections 18A, the second pad portions 16B, the second connections 18B, the lattices 28, and the like) to the entire conductive part as a whole. For example, a square lattice having a line width of 15 μm and a pitch of 300 μm has an opening ratio of 90%.

### [Light-Transmitting Portion]

In the present embodiment, the term “light-transmitting portion” implies a portion having light transmittance, apart from the conductive metal portions in the first conductive film 10A and the second conductive film 10B. As described above, the transmittance of the light-transmitting portion, which is a minimum transmittance value in a wavelength region of 380 to 780 nm obtained neglecting the light absorption and reflection of the first transparent substrate 12A and the second transparent substrate 12B, is 90% or greater, preferably is 95% or greater, more preferably, is 97% or greater, further preferably, is 98% or greater, and most preferably, is 99% or greater.

Exposure preferably is carried out using a glass mask method or a laser lithography pattern exposure method.

### [First Conductive Film 10A and Second Conductive Film 10B]

In the first conductive film 10A and the second conductive film 10B according to the present embodiment, the thickness of the first transparent substrate 12A and the second transparent substrate 12B preferably is 5 to 350 μm, and more preferably, is 30 to 150 μm. In the case that the thickness thereof is within the range of 5 to 350 μm, a desired visible light transmittance can be obtained, and the substrates can be easily handled.

The thickness of the metallic silver portion formed on the first transparent substrate 12A or the second transparent substrate 12B may be selected appropriately by controlling the thickness of the coating liquid for the silver salt-containing layer applied to the first transparent substrate 12A or the second transparent substrate 12B. The thickness of the metallic silver portion may be selected within a range of 0.001 to 0.2 mm, preferably is 30 μm or less, more preferably, is 20 μm or less, further preferably, is 0.01 to 9 μm, and most preferably, is 0.05 to 5 μm. The metallic silver portion preferably is formed in a patterned shape. The metallic silver portion may have a monolayer structure or a multilayer structure containing two or more layers. In the case that the metallic silver portion has a patterned multilayer structure containing two or more layers, the layers may have different wavelength color sensitivities so as to be sensitive to different wavelengths. In this case, different patterns can be formed in the layers by using exposure lights having different wavelengths.

For use in a touch panel, the conductive metal portion preferably has a smaller thickness. Since the thickness is reduced, the viewing angle and visibility of the display panel are improved. Thus, the thickness of the layer of the conductive metal on the conductive metal portion preferably is less than 9 μm, more preferably, is 0.1 μm or greater but less than 5 μm, and further preferably, is 0.1 μm or greater but less than 3 μm.

In the present embodiment, as noted above, the thickness of the metallic silver portion can be controlled by changing the coating thickness of the silver salt-containing layer, and the thickness of the conductive metal particle layer can be controlled in at least one of the physical development treatment and the plating treatment, whereby the first conductive film 10A and the second conductive film 10B having a thickness of less than 5 μm, and preferably less than 3 μm, can easily be produced.

Plating or the like need not necessarily be carried out in the method for producing the first conductive film 10A and the second conductive film 10B according to the present embodiment. This is because, in the present method, a desired surface resistance can be obtained by controlling the applied silver amount and the silver/binder volume ratio of the silver salt emulsion layer. A calender treatment or the like may also be carried out as necessary.

(Film Hardening Treatment after Development Treatment)

It is preferred, after the silver salt emulsion layer has been developed, for the resultant product to be immersed in a hardener and subjected to a film hardening treatment. Examples of hardeners, for example, can include dialdehydes (such as glutaraldehyde, adipaldehyde, and 2,3-dihydroxy-1,4-dioxane) and boric acid, as described in Japanese Laid-Open Patent Publication No. 2-141279.

An additional functional layer, such as an antireflection layer or a hard coat layer, may be formed in the conductive films 10A, 10B according to the present embodiment.

### [Calender Treatment]

The developed metallic silver portion may be smoothened by a calender treatment. The conductivity of the metallic silver portion can be increased significantly by such a calender treatment. The calender treatment may be carried out using a calender roll unit. The calender roll unit generally includes a pair of rolls.

The roll used in the calender treatment may be composed of a metal or a plastic (such as an epoxy, polyimide, polyamide, or polyimide-amide). In particular, in the case that the photosensitive material has an emulsion layer on both sides thereof, preferably the photosensitive material is treated with a pair of metal rolls. In the case that the photosensitive material has an emulsion layer on only one side thereof, the photosensitive material may be treated with a combination of a metal roll and a plastic roll from the standpoint of preventing wrinkling. The upper limit of the line pressure preferably is 1960 N/cm (200 kgf/cm, corresponding to a surface pressure of 699.4 kgf/cm²) or greater, and more preferably, is 2940 N/cm (300 kgf/cm, corresponding to a surface pressure of 935.8 kgf/cm²) or greater. The upper limit of the line pressure preferably is 6880 N/cm (700 kgf/cm) or less.

A smoothing treatment, such as a calender treatment or the like, preferably is carried out at a temperature of 10° C. (without temperature control) to 100° C. The preferred treatment temperature range depends on the density and shape of the metal mesh or metal wiring pattern, the type of the binder, etc. More preferably, the temperature is 10° C. (without temperature control) to 50° C. in general.

In the present invention, the technologies of the following Japanese Laid-Open Patent Publications and PCT International Publication Numbers shown in Tables 1 and 2 can appropriately be used in combination. In the following Tables 1 and 2, conventional notations such as “Japanese Laid-Open Patent Publication No.”, “International Publication No.”, “Pamphlet No. WO”, etc., have been omitted.

TABLE 1

| | | | | |
|---|---|---|---|---|
| 2004-221564 | 2004-221565 | 2007-200922 | 2006-352073 | 2007-129205 |
| 2007-235115 | 2007-207987 | 2006-012935 | 2006-010795 | 2006-228469 |
| 2006-332459 | 2009-21153 | 2007-226215 | 2006-261315 | 2007-072171 |
| 2007-102200 | 2006-228473 | 2006-269795 | 2006-269795 | 2006-324203 |
| 2006-228478 | 2006-228836 | 2007-009326 | 2006-336090 | 2006-336099 |
| 2006-348351 | 2007-270321 | 2007-270322 | 2007-201378 | 2007-335729 |
| 2007-134439 | 2007-149760 | 2007-208133 | 2007-178915 | 2007-334325 |
| 2007-310091 | 2007-116137 | 2007-088219 | 2007-207883 | 2007-013130 |
| 2005-302508 | 2008-218784 | 2008-227350 | 2008-227351 | 2008-244067 |
| 2008-267814 | 2008-270405 | 2008-277675 | 2008-277676 | 2008-282840 |
| 2008-283029 | 2008-288305 | 2008-288419 | 2008-300720 | 2008-300721 |
| 2009-4213 | 2009-10001 | 2009-16526 | 2009-21334 | 2009-26933 |
| 2008-147507 | 2008-159770 | 2008-159771 | 2008-171568 | 2008-198388 |
| 2008-218096 | 2008-218264 | 2008-224916 | 2008-235224 | 2008-235467 |
| 2008-241987 | 2008-251274 | 2008-251275 | 2008-252046 | 2008-277428 |

TABLE 2

| | | | | |
|---|---|---|---|---|
| 2006/001461 | 2006/088059 | 2006/098333 | 2006/098336 | 2006/098338 |
| 2006/098335 | 2006/098334 | 2007/001008 | | |

### EXAMPLES

Examples of the present invention will be described more specifically below. Materials, amounts, ratios, treatment contents, treatment procedures, and the like, which are used in examples, may be appropriately changed without departing from the essential scope of the present invention. Therefore, the following specific examples should be considered in all respects as illustrative and not restrictive.

In the conductive film stacks 10 of Examples 1 to 8 and Reference Examples 1 and 2, surface resistance and transmittance were measured, and the presence of moiré patterns and visibility were evaluated. The properties, measurement results, and evaluation results of Examples 1 to 8 and Reference Examples 1 and 2 are shown below in Table 3.

### Examples 1 to 8 and Reference Examples 1 and 2

### Photosensitive Silver Halide Material

An emulsion containing an aqueous medium, gelatin, and silver iodobromochloride particles was prepared. The amount of gelatin was 10.0 g per 150 g of Ag, and the silver iodobromochloride particles had an I content of 0.2 mol %, a Br content of 40 mol %, and an average spherical equivalent diameter of 0.1 μm.

K₃Rh₂Br₉ and K₂IrCl₆ were added to the emulsion at a concentration of 10⁻⁷ (mol/mol-Ag) in order to dope the silver bromide particles with Rh and Ir ions. Na₂PdCl₄ was further added to the emulsion, and the resultant emulsion was subjected to gold-sulfur sensitization using chlorauric acid and sodium thiosulfate. Thereafter, the emulsion and a gelatin hardening agent were applied to each of the first transparent substrate 12A and the second transparent substrate 12B, which were composed of polyethylene terephthalate (PET), such that the amount of applied silver was 10 g/m² and the Ag/gelatin volume ratio was 2/1.

The PET support body had a width of 30 cm, and the emulsion was applied thereto at a width of 25 cm and a length of 20 m. Both edge portions, each having a width of 3 cm, were cut off from the PET support body in order to obtain a roll of a photosensitive silver halide material having a width of 24 cm.

### (Exposure)

An A4 (210 mm×297 mm) sized area of the first transparent substrate 12A was exposed with the pattern of the first conductive film 10A shown in FIGS. 1 and 3, and an A4 sized area of the second transparent substrate 12B was exposed with the pattern of the second conductive film 10B shown in FIGS. 7 and 8. Exposure was carried out using parallel light from a high-pressure mercury lamp light source, and using the photomasks having the patterns mentioned above.

### (Development Treatment)

The following chemical compounds were included in 1 L of the developing solution.

| | |
|---|---|
| Hydroquinone | 20 g |
| Sodium sulfite | 50 g |
| Potassium carbonate | 40 g |
| Ethylenediaminetetraacetic acid | 2 g |
| Potassium bromide | 3 g |
| Polyethylene glycol 2000 | 1 g |
| Potassium hydroxide | 4 g |
| pH | Controlled at 10.3 |

The following chemical compounds were included in 1 L of the fixing solution.

| | | |
|---|---|---|
| Ammonium thiosulfate solution (75%) | 300 | ml |
| Ammonium sulfite monohydrate | 25 | g |
| 1,3-Diaminopropanetetraacetic acid | 8 | g |
| Acetic acid | 5 | g |
| Aqueous ammonia (27%) | 1 | g |

| | |
|---|---|
| pH | Controlled at 6.2 |

The exposed photosensitive material was treated with the aforementioned treatment agents, using an automatic processor FG-710PTS manufactured by FUJIFILM Corporation under the following conditions. A development treatment was carried out at 35° C. for 30 seconds, a fixation treatment was carried out at 34° C. for 23 seconds, and thereafter, a water washing treatment was carried out for 20 seconds under running water at a flow rate of 5 L/min.

### Example 1

In the conductive parts (containing the first conductive patterns 20A and the second conductive patterns 20B) of the produced first conductive film 10A and second conductive film 10B, the line width was 1 μm, the side length of the lattice 28 was 100 μm, and the side length of the pad portion (the first pad portion 16A or the second pad portion 16B) was 3 mm.

### Example 2

The first conductive film 10A and the second conductive film 10B of Example 2 were produced in the same manner as Example 1, except that the line width of the conductive part was 3 μm, the side length of the lattice 28 was 150 μm, and the side length of the pad portion was 4 mm.

### Example 3

The first conductive film 10A and the second conductive film 10B of Example 3 were produced in the same manner as Example 1, except that the line width of the conductive part was 4 μm, the side length of the lattice 28 was 210 μm, and the side length of the pad portion was 5 mm.

### Example 4

The first conductive film 10A and the second conductive film 10B of Example 4 were produced in the same manner as Example 1, except that the line width of the conductive part was 5 μm, the side length of the lattice 28 was 250 μm, and the side length of the pad portion was 5 mm.

### Example 5

The first conductive film 10A and the second conductive film 10B of Example 5 were produced in the same manner as Example 1, except that the line width of the conductive part was 8 μm, the side length of the lattice 28 was 300 μm, and the side length of the pad portion was 6 mm.

### Example 6

The first conductive film 10A and the second conductive film 10B of Example 6 were produced in the same manner as Example 1, except that the line width of the conductive part was 9 μm, the side length of the lattice 28 was 300 μm, and the side length of the pad portion was 10 mm.

### Example 7

The first conductive film 10A and the second conductive film 10B of Example 7 were produced in the same manner as Example 1, except that the line width of the conductive part was 10 μm, the side length of the lattice 28 was 300 μm, and the side length of the pad portion was 10 mm.

### Example 8

The first conductive film 10A and the second conductive film 10B of Example 8 were produced in the same manner as Example 1, except that the line width of the conductive part was 15 μm, the side length of the lattice 28 was 400 μm, and the side length of the pad portion was 10 mm.

### Reference Example 1

The first conductive film 10A and the second conductive film 10B of Reference Example 1 were produced in the same manner as Example 1, except that the line width of the conductive part was 0.5 μm, the side length of the lattice 28 was 40 μm, and the side length of the pad portion was 3 mm.

### Reference Example 2

The first conductive film 10A and the second conductive film 10B of Reference Example 2 were produced in the same manner as Example 1, except that the line width of the conductive part was 25 μm, the side length of the lattice 28 was 500 μm, and the side length of the pad portion was 12 mm.

### (Surface Resistance Measurement)

In each of the first conductive film 10A and the second conductive film 10B, the surface resistivity values of 10 points, which were randomly selected, were measured by a LORESTA GP (Model No. MCP-T610) resistivity meter manufactured by Dia Instruments Co., Ltd. utilizing an in-line four-probe method (ASP), and the average of the measured values was obtained to evaluate the detection accuracy.

### (Transmittance Measurement)

In each of the first conductive film 10A and the second conductive film 10B, the transmittance value was measured by a spectrophotometer to evaluate transparency.

(Moiré Pattern Evaluation)

In Examples 1 to 8 and Reference Examples 1 and 2, the first conductive film 10A was stacked on the second conductive film 10B so as to prepare the conductive film stack 50, and the conductive film stack 50 was attached to a display screen of a liquid crystal display device in order to produce the touch panel 100. The touch panel 100 was fixed to a turntable, and the liquid crystal display device was operated to display a white color. The occurrence of moiré patterns was visually observed and evaluated while turning the turntable within a bias angle range of −45° to +45°.

The occurrence of moiré patterns was observed at a distance of 1.5 m from the display screen of the liquid crystal display device. The conductive film stack 50 was evaluated as “Good” on the condition that moiré patterns were not visible, as “Fair” on the condition that the moiré patterns were slightly visible to an acceptable extent, or as “Poor” on the condition that the moiré patterns were highly visible.

### (Visibility Evaluation)

Before performing the moiré pattern evaluation, the touch panel 100 was fixed to the turntable, the liquid crystal display device was operated to display a white color, and an evaluation was performed by the naked eye in order to judge whether or not a thickened line or a black point was formed in the touch panel 100, and to judge whether or not boundaries between the first pad portions 16A and the second pad portions 16B were visible in the touch panel 100.

TABLE 3

| | | | Side length | | | | |
|---|---|---|---|---|---|---|---|
| | Line width of | Side length | of pad | Surface | | | |
| | conductive part | of lattice | portion | resistance | Transmittance | Moire | Visibility |
| | (μm) | (μm) | (mm) | (Ω/sq) | (%) | evaluation | evaluation |
| Reference Example 1 | 0.5 | 40 | 3 | 1 k or more | 80 | Good | Good |
| Example 1 | 1 | 100 | 3 | 55 | 85 | Good | Good |
| Example 2 | 3 | 150 | 4 | 55 | 86 | Good | Good |
| Example 3 | 4 | 210 | 5 | 50 | 87 | Good | Good |
| Example 4 | 5 | 250 | 5 | 40 | 88 | Good | Good |
| Example 5 | 8 | 300 | 6 | 50 | 87 | Good | Good |
| Example 6 | 9 | 300 | 10 | 45 | 86 | Good | Good |
| Example 7 | 10 | 300 | 10 | 40 | 86 | Good | Good |
| Example 8 | 15 | 400 | 10 | 38 | 85 | Fair | Fair |
| Reference Example 2 | 25 | 500 | 12 | 33 | 83 | Poor | Poor |

As shown in Table 3, although the conductive films of Reference Example 1 produced excellent results in the evaluations of moiré patterns and visibility, the conductive films had a surface resistance of 1 kohm/sq or greater. Thus, the conductive films of Reference Example 1 tended to exhibit low conductivity and insufficient detection sensitivity. Further, although the conductive films of Reference Example 2 exhibited excellent conductivity and transmittance, moiré patterns were highly visible, and the conductive parts per se were highly visible to the naked eye such that visibility was deteriorated.

In contrast, among Examples 1 to 8, the conductive films of Examples 1 to 7 were excellent in terms of conductivity, transmittance, moiré patterns, and visibility. The conductive films of Example 8 were inferior to those of Examples 1 to 7 in terms of moiré patterns and visibility, but the moiré patterns were only slightly visible to an acceptable extent, such that the image displayed on the display device was not deteriorated.

A projected capacitive touch panel was produced using each of the conductive film stacks 50 of Examples 1 to 8. Being operated by a finger touch, the touch panels exhibited a high response speed and excellent detection sensitivity. Furthermore, In a case where two or more points were touched, the touch panels exhibited the same excellent properties. Thus, it was confirmed that the touch panels were capable of multi-touch detection.

It is to be understood that the conductive film and the touch panel of the present invention are not limited to the embodiments described above. Various changes and modifications may be made to the embodiments without departing from the scope of the present invention.

1. A conductive film comprising a substrate and a conductive part formed on one main surface of the substrate, wherein:
the conductive part contains two or more conductive patterns composed of a thin metal wire;
the conductive patterns each contain a plurality of pad portions connected by connections;
the pad portions each contain a first spiral extending from one of the connections, a second spiral extending from an opposite connection, and a linkage for linking the first spiral and the second spiral;
the first spiral and the second spiral each contain a combination of a plurality of lattices; and
the linkage contains a plurality of conductive wires.

2. The conductive film according to claim 1, wherein edges of the first spiral and the second spiral each have a concavo-convex shape having peaks and troughs at vertices of the lattices.

3. The conductive film according to claim 1, wherein each of a plurality of the conductive wires in the linkage have a straight line shape.

4. The conductive film according to claim 1, wherein the conductive part contains a dummy pattern between the conductive patterns, the dummy pattern being composed of a thin metal wire that is not connected to the conductive patterns.

5. The conductive film according to claim 4, wherein the dummy pattern is positioned between the connection in one of the conductive patterns and the connection in an opposite conductive pattern.

6. The conductive film according to claim 1, wherein:
edges of the first spiral and the second spiral each have two or more long sides and a protrusion;
the long sides each contain sides of the lattices arranged adjacently along a straight line; and
the protrusion is composed of a thin metal wire, which extends perpendicularly from at least one of the long sides.

7. The conductive film according to claim 1, wherein the lattices have a side length of 100 to 400 μm.

8. The conductive film according to claim 1, wherein the lattices have a line width of 1 to 15 μm.

9. A conductive film comprising a substrate, a first conductive part formed on one main surface of the substrate, and a second conductive part formed on another main surface of the substrate, wherein:
the first conductive part contains two or more first conductive patterns composed of a thin metal wire;
the first conductive patterns each contain a plurality of first pad portions connected by first connections;
the second conductive part contains two or more second conductive patterns composed of a thin metal wire;
the second conductive patterns each contain a plurality of second pad portions connected by second connections;
the first pad portions each contain a first spiral extending from one of the first connections, a second spiral extending from an opposite first connection, and a first linkage for linking the first spiral and the second spiral;
the second pad portions each contain a third spiral extending from one of the second connections, a fourth spiral extending from an opposite second connection, and a second linkage for linking the third spiral and the fourth spiral;
the first spiral to the fourth spiral each contain a combination of a plurality of lattices;
the first linkage and the second linkage each contain a plurality of conductive wires; and
the first conductive patterns and the second conductive patterns are arranged such that the first linkage and the second linkage intersect in a substantially perpendicular manner.

10. The conductive film according to claim 9, wherein edges of the first spiral to the fourth spiral each have a concavo-convex shape having peaks and troughs at vertices of the lattices.

11. The conductive film according to claim 9, wherein the first conductive patterns and the second conductive patterns are arranged such that the second connection is positioned between adjacent first conductive patterns, and the first connection is positioned between adjacent second conductive patterns.

12. The conductive film according to claim 9, wherein the first conductive patterns and the second conductive patterns are arranged such that the third spiral or the fourth spiral in the second conductive pattern is positioned between the first spiral and the second spiral in the first conductive pattern, and the first spiral or the second spiral in the first conductive pattern is positioned between the third spiral and the fourth spiral in the second conductive pattern.

13. The conductive film according to claim 9, wherein:
the first conductive part contains a first dummy pattern between the first conductive patterns, the first dummy pattern being composed of a thin metal wire that is not connected to the first conductive patterns; and
the second conductive part contains a second dummy pattern between the second conductive patterns, the second dummy pattern being composed of a thin metal wire that is not connected to the second conductive patterns.

14. The conductive film according to claim 13, wherein:
the first dummy pattern is positioned between the first connection in one of the first conductive patterns and the first connection in an opposite first conductive pattern; and
the second dummy pattern is positioned between the second connection in one of the second conductive patterns and the second connection in an opposite second conductive pattern.

15. The conductive film according to claim 14, wherein the first conductive patterns and the second conductive patterns are arranged such that the second connection is positioned between the first dummy patterns, and the first connection is positioned between the second dummy patterns.

16. The conductive film according to claim 9, wherein the number of lattices in the first spiral and the second spiral in the first conductive pattern is smaller than the number of lattices in the third spiral and the fourth spiral in the second conductive pattern.

17. The conductive film according to claim 9, wherein:
edges of the first spiral and the second spiral each have two or more first long sides and a first protrusion;
the first long sides each contain sides of the lattices arranged adjacently along a straight line;
the first protrusion is composed of a thin metal wire, which extends perpendicularly from at least one of the first long sides;
edges of the third spiral and the fourth spiral each have two or more second long sides and a second protrusion;
the second long sides each contain sides of the lattices arranged adjacently along a straight line; and
the second protrusion is composed of a thin metal wire, which extends perpendicularly from at least one of the second long sides.

18. The conductive film according to claim 17, wherein the first long side that has the first protrusion and the second long side that does not have the second protrusion are arranged in facing relation to each other.

19. The conductive film according to claim 17, wherein the first long side that does not have the first protrusion and the second long side that has the second protrusion are arranged in facing relation to each other.

20. The conductive film according to claim 9, wherein the lattices have a side length of 100 to 400 μm.

21. The conductive film according to claim 9, wherein the lattices have a line width of 1 to 15 μm.

22. A touch panel comprising a conductive film, which is used in a display panel of a display device, wherein:
the conductive film contains a substrate and a conductive part formed on one main surface of the substrate;
the conductive part contains two or more conductive patterns composed of a thin metal wire;
the conductive patterns each contain a plurality of pad portions connected by connections;
the pad portions each contain a first spiral extending from one of the connections, a second spiral extending from an opposite connection, and a linkage for linking the first spiral and the second spiral;
the first spiral and the second spiral each contain a combination of a plurality of lattices; and
the linkage contains a plurality of conductive wires.

23. A touch panel comprising a conductive film, which is used in a display panel of a display device, wherein:
the conductive film contains a substrate, a first conductive part formed on one main surface of the substrate, and a second conductive part formed on another main surface of the substrate;
the first conductive part contains two or more first conductive patterns composed of a thin metal wire;
the first conductive patterns each contain a plurality of first pad portions connected by first connections;
the second conductive part contains two or more second conductive patterns composed of a thin metal wire;
the second conductive patterns each contain a plurality of second pad portions connected by second connections;
the first pad portions each contain a first spiral extending from one of the first connections, a second spiral extending from an opposite first connection, and a first linkage for linking the first spiral and the second spiral;
the second pad portions each contain a third spiral extending from one of the second connections, a fourth spiral extending from an opposite second connection, and a second linkage for linking the third spiral and the fourth spiral;
the first spiral to the fourth spiral each contain a combination of a plurality of lattices;
the first linkage and the second linkage each contain a plurality of conductive wires; and
the first conductive patterns and the second conductive patterns are arranged such that the first linkage and the second linkage intersect in a substantially perpendicular manner.
